(19) United States
(12) Patent Application Publication
(10) Pub. No.: US 2023/0261028 A1
(43) Pub. Date: Aug. 17, 2023

(54) SOLID-STATE IMAGING DEVICE AND ELECTRONIC APPARATUS

(71) Applicant: SONY SEMICONDUCTOR SOLUTIONS CORPORATION, KANAGAWA (JP)

(72) Inventor: TETSUYA UCHIDA, KANAGAWA (JP)

(21) Appl. No.: 18/003,549

(22) PCT Filed: Jun. 16, 2021
(86) PCT No.: PCT/JP2021/022816

§ 371 Date: Dec. 28, 2022

(30) Foreign Application Priority Data
Jul. 8, 2020 (JP) 2020-118067

(51) Int. Cl. H01L 27/146

(52) U.S. Cl. CPC H01L 27/14647; H01L 27/1463; H01L 27/14614

(57) ABSTRACT

A solid-state imaging device includes: a light receiving surface; and a plurality of pixels that is disposed in a matrix at positions opposed to the light receiving surface. The respective pixels have different depths from the light receiving surface. Each of the pixels includes a plurality of photoelectric conversion sections and a plurality of electric charge holding sections one or more of which are provided for each of the plurality of photoelectric conversion sections. The photoelectric conversion sections each photoelectrically convert light coming through the light receiving surface. The electric charge holding sections each hold electric charge transferred from the corresponding photoelectric conversion section. Each of the pixels further includes a plurality of transfer transistors one or more of which are provided for each of the photoelectric conversion sections. The plurality of transfer transistors each includes a vertical gate electrode that reaches at least the corresponding photoelectric conversion section and transfers electric charge from the corresponding photoelectric conversion section to the corresponding electric charge holding section. In each of the pixels, the plurality of transfer transistors is disposed along a border between the two or four pixels adjacent to each other.

### TECHNICAL FIELD

The present disclosure relates to a solid-state imaging device and an electronic apparatus.

### BACKGROUND ART

Methods are developed of dispersing light by forming a plurality of photodiodes per pixel in a substrate in the depth direction to prevent a CCD image sensor or a CMOS image sensor serving as a solid-state imaging device from having a false color (see, for example, PTL 1).

### CITATION LIST

### Patent Literature

PTL 1: Japanese Unexamined Patent Application Publication No. 2009-295937

### SUMMARY OF THE INVENTION

Incidentally, in the solid-state imaging device described above, the electric charge obtained by each of the photodiodes is transferred to a floating diffusion through a vertical transistor. The electric charge of light entering each of the pixels resulting from photoelectric conversion in the vertical transistor is, however, difficult for a photodiode to absorb. This may decrease the sensitivity. It is thus desirable to provide a solid-state imaging device that makes it possible to suppress a decrease in sensitivity and an electronic apparatus including the solid-state imaging device.

A solid-state imaging device according to an embodiment of the present disclosure includes: a light receiving surface; and a plurality of pixels that is disposed in a matrix at positions opposed to the light receiving surface. The respective pixels have different depths from the light receiving surface. Each of the pixels includes a plurality of photoelectric conversion sections and a plurality of electric charge holding sections one or more of which are provided for each of the plurality of photoelectric conversion sections. The photoelectric conversion sections each photoelectrically convert light coming through the light receiving surface. The electric charge holding sections each hold electric charge transferred from the corresponding photoelectric conversion section. Each of the pixels further includes a plurality of transfer transistors one or more of which are provided for each of the photoelectric conversion sections. The plurality of transfer transistors each includes a vertical gate electrode that reaches at least the corresponding photoelectric conversion section and transfers electric charge from the corresponding photoelectric conversion section to the corresponding electric charge holding section. In each of the pixels, the plurality of transfer transistors is disposed along a border between the two or four pixels adjacent to each other.

An electronic apparatus according to an embodiment of the present disclosure includes: a solid-state imaging device; and a signal processing circuit. The solid-state imaging device outputs a pixel signal corresponding to incident light. The signal processing circuit processes the pixel signal. The solid-state imaging device provided in the electronic apparatus has the same configuration as that of the solid-state imaging device described above.

In each of the pixels in the solid-state imaging device and the electronic apparatus according to the respective embodiments of the present disclosure, the plurality of transfer transistors is disposed along the border between the two or four pixels adjacent to each other. This makes it possible to reduce the proportion of light entering each pixel that is photoelectrically converted by the respective transfer transistors as compared with the proportion of light that is photoelectrically converted by the respective transfer transistors disposed near the middle of each pixel.

### BRIEF DESCRIPTION OF DRAWING

FIG. 1 is a diagram illustrating an example of a schematic configuration of a solid-state imaging device according to a first embodiment of the present disclosure.

FIG. 2 is a diagram illustrating an example of a circuit configuration of a sensor pixel in FIG. 1.

FIG. 3 is a diagram illustrating an example of a planar configuration of a pixel array section in FIG. 1.

FIG. 4 is a diagram illustrating an example of a horizontal cross-sectional configuration of the pixel array section in FIG. 3.

FIG. 5 is a diagram illustrating an example of the horizontal cross-sectional configuration of the pixel array section in FIG. 3.

FIG. 6 is a diagram illustrating an example of the horizontal cross-sectional configuration of the pixel array section in FIG. 3.

FIG. 7 is a diagram illustrating an example of the horizontal cross-sectional configuration of the pixel array section in FIG. 3.

FIG. 8 is a diagram illustrating an example of the horizontal cross-sectional configuration of the pixel array section in FIG. 3.

FIG. 9 is a diagram illustrating an example of a vertical cross-sectional configuration of the pixel array section in FIG. 3 taken along an A-A line.

FIG. 10 is a diagram illustrating an example of a vertical cross-sectional configuration of the pixel array section in FIG. 3 taken along a B-B line.

FIG. 11 is a diagram illustrating a modification example of the circuit configuration of the sensor pixel in FIG. 1.

FIG. 12 is a diagram illustrating an example of the planar configuration of the pixel array section in FIG. 11.

FIG. 13 is a diagram illustrating an example of a horizontal cross-sectional configuration of the pixel array section in FIG. 11.

FIG. 14 is a diagram illustrating an example of the horizontal cross-sectional configuration of the pixel array section in FIG. 11.

FIG. 15 is a diagram illustrating an example of the horizontal cross-sectional configuration of the pixel array section in FIG. 11.

FIG. 16 is a diagram illustrating an example of the horizontal cross-sectional configuration of the pixel array section in FIG. 11.

FIG. 17 is a diagram illustrating an example of a vertical cross-sectional configuration of the pixel array section in FIG. 11 taken along an A-A line.

FIG. 18 is a diagram illustrating an example of a vertical cross-sectional configuration of the pixel array section in FIG. 11 taken along a B-B line.

FIG. 19 is a diagram illustrating a modification example of the circuit configuration of the sensor pixel in FIG. 1.

FIG. 20 is a diagram illustrating an example of a planar configuration of the pixel array section in FIG. 19.

FIG. 21 is a diagram illustrating an example of a vertical cross-sectional configuration of the pixel array section in FIG. 20 taken along an A-A line.

FIG. 22 is a diagram illustrating an example of a vertical cross-sectional configuration of the pixel array section in FIG. 20 taken along a B-B line.

FIG. 23 is a diagram illustrating a modification example of the circuit configuration of the sensor pixel in FIG. 1.

FIG. 24 is a diagram illustrating an example of a vertical cross-sectional configuration of a pixel array section including the sensor pixel in FIG. 23.

FIG. 25 is a diagram illustrating an example of the vertical cross-sectional configuration of the pixel array section including the sensor pixel in FIG. 23.

FIG. 26 is a diagram illustrating a modification example of the planar configuration of the pixel array section in FIG. 1.

FIG. 27 is a diagram illustrating an example of the horizontal cross-sectional configuration of the pixel array section in FIG. 26.

FIG. 28 is a diagram illustrating an example of the horizontal cross-sectional configuration of the pixel array section in FIG. 26.

FIG. 29 is a diagram illustrating an example of the horizontal cross-sectional configuration of the pixel array section in FIG. 26.

FIG. 30 is a diagram illustrating an example of the horizontal cross-sectional configuration of the pixel array section in FIG. 26.

FIG. 31 is a diagram illustrating an example of the horizontal cross-sectional configuration of the pixel array section in FIG. 26.

FIG. 32 is a diagram illustrating an example of a vertical cross-sectional configuration of the pixel array section in FIG. 26 taken along a B-B line.

FIG. 33 is a diagram illustrating a modification example of the planar configuration of the pixel array section in FIG. 1.

FIG. 34 is a diagram illustrating an example of a horizontal cross-sectional configuration of the pixel array section in FIG. 33.

FIG. 35 is a diagram illustrating an example of the horizontal cross-sectional configuration of the pixel array section in FIG. 33.

FIG. 36 is a diagram illustrating an example of the horizontal cross-sectional configuration of the pixel array section in FIG. 33.

FIG. 37 is a diagram illustrating an example of the horizontal cross-sectional configuration of the pixel array section in FIG. 33.

FIG. 38 is a diagram illustrating an example of the horizontal cross-sectional configuration of the pixel array section in FIG. 33.

FIG. 39 is a diagram illustrating an example of a vertical cross-sectional configuration of the pixel array section in FIG. 33 taken along an A-A line.

FIG. 40 is a diagram illustrating an example of a vertical cross-sectional configuration of the pixel array section in FIG. 33 taken along a B-B line.

FIG. 41 is a diagram illustrating a modification example of the vertical cross-sectional configuration of the pixel array section in FIG. 3 taken along the A-A line.

FIG. 42 is a diagram illustrating an example of a schematic configuration of an imaging system according to a second embodiment of the present disclosure.

FIG. 43 is a block diagram depicting an example of schematic configuration of a vehicle control system.

FIG. 44 is a diagram of assistance in explaining an example of installation positions of an outside-vehicle information detecting section and an imaging section.

FIG. 45 is a view depicting an example of a schematic configuration of an endoscopic surgery system.

FIG. 46 is a block diagram depicting an example of a functional configuration of a camera head and a camera control unit (CCU).

### Modes for Carrying Out the Invention

The following describes embodiments of the present disclosure in detail with reference to the drawings. It is to be noted that description is given in the following order.

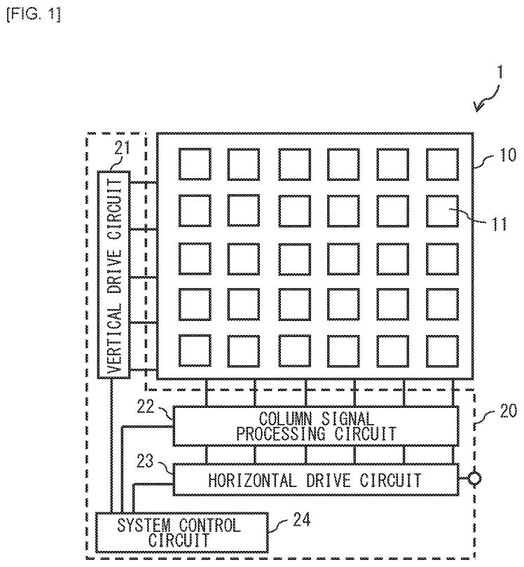

1. First Embodiment (Solid-State Imaging Device) . . . FIGS. 1 to 10 An example in which there are provided transfer transistors at the border between four pixels adjacent to each other

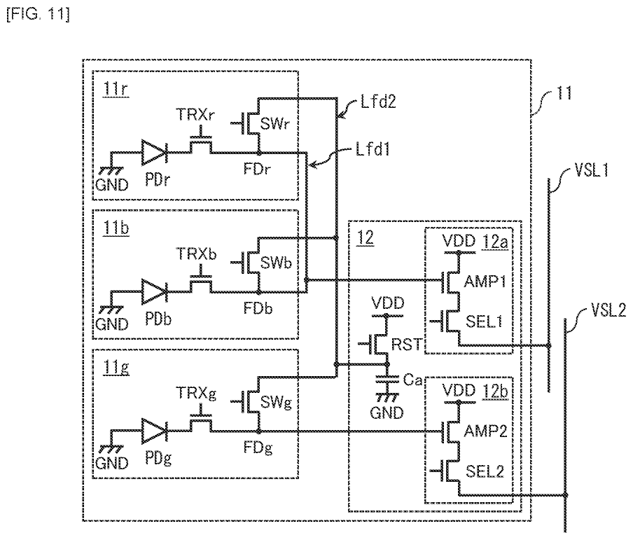

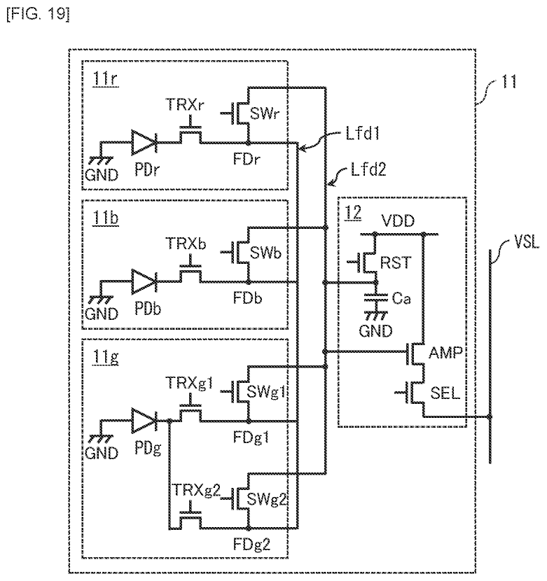

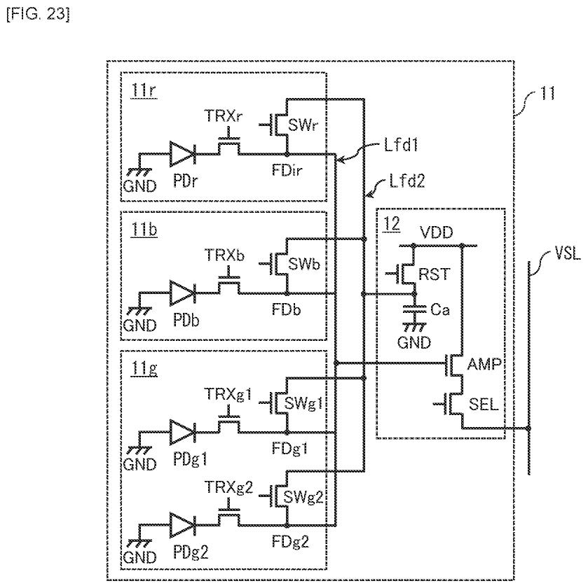

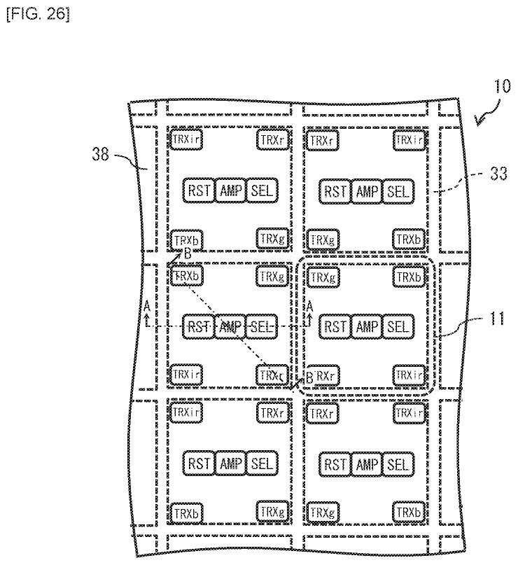

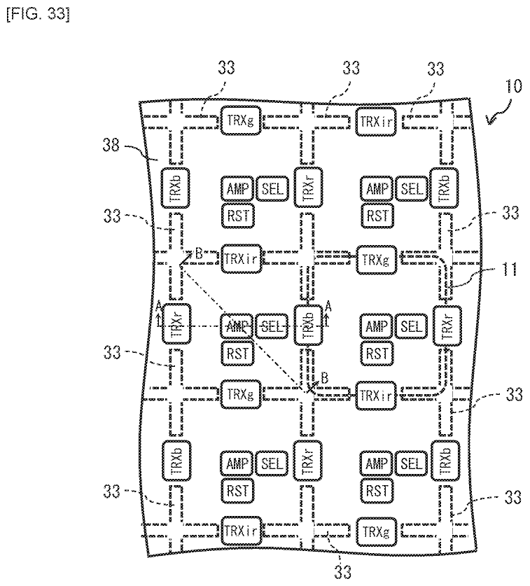

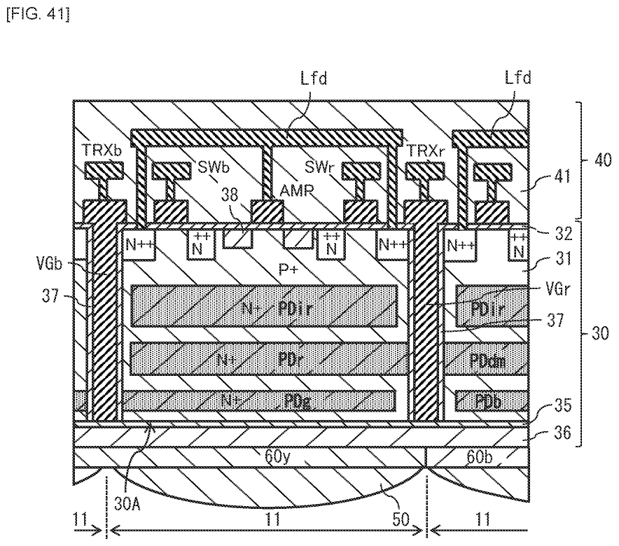

2. Modification Examples (Solid-State Imaging Devices) of First Embodiment Modification Example A: An example in which there are provided two amplifiers in one pixel . . . FIGS. 11 to 18 Modification Example B: An example in which there are provided two transfer transistors in one photoelectric conversion element . . . FIGS. 19 to 22 Modification Example C: An example in which there are provided two photoelectric conversion elements having the same emission color in one pixel . . . FIGS. 23 to 25 Modification Example D: An example in which there are provided transfer transistors at the four corners of one pixel . . . FIGS. 26 to 32 Modification Example E: An example in which there are provided transfer transistors at the border between two pixels adjacent to each other . . . FIGS. 33 to 40 Modification Example F: An example in which there is provided a color filter . . . FIG. 41

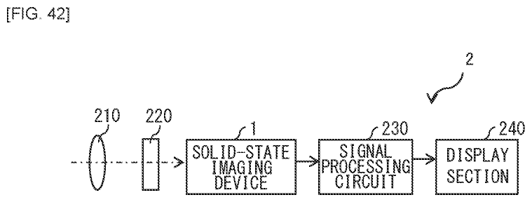

3. Second Embodiment (Imaging System) . . . FIG. 42

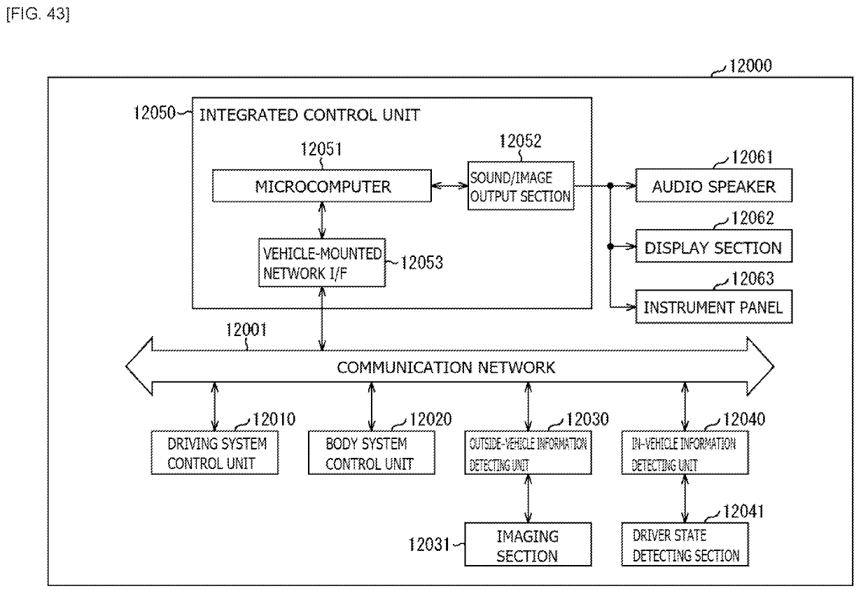

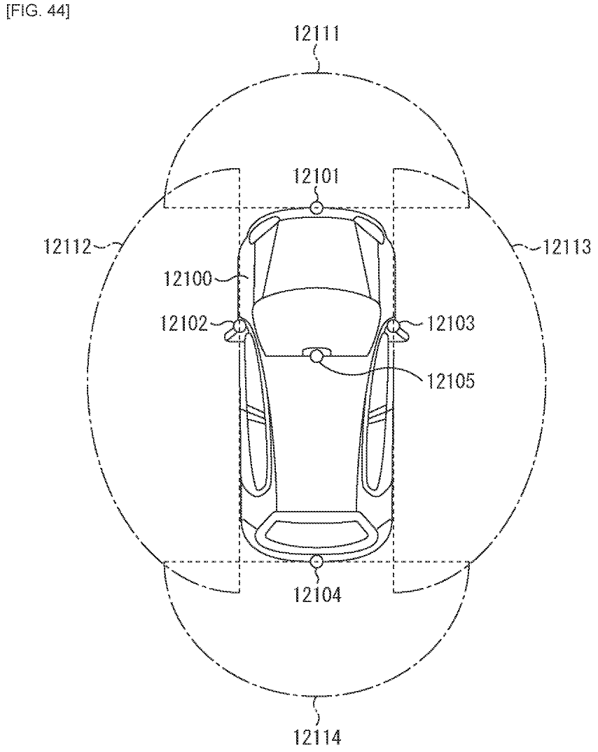

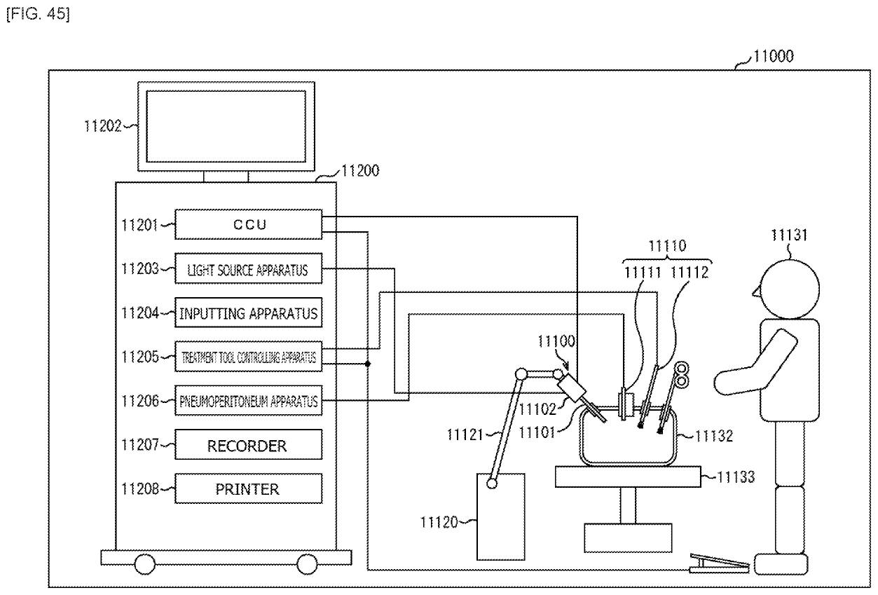

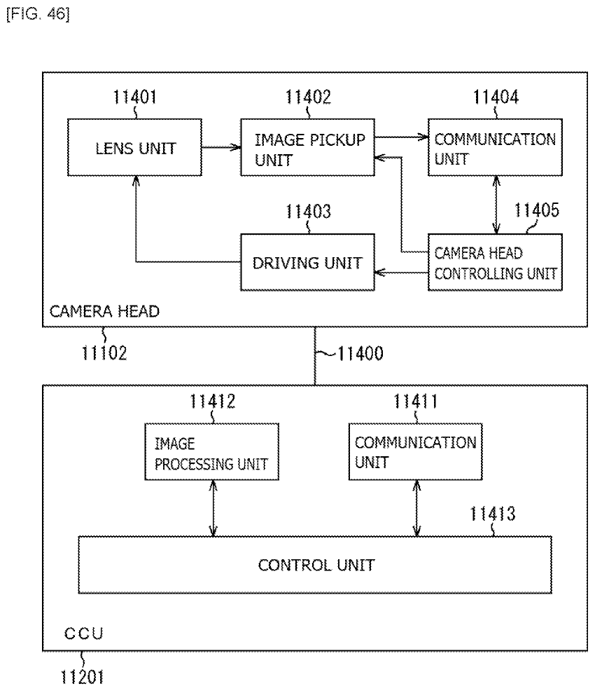

4. Practical Application Examples Example of Practical Application to Mobile Body . . . FIGS. 43 and 44 Example of Practical Application to Endoscopic Surgery System . . . FIGS. 45 and 46

<1. First Embodiment>

[Configuration]

FIG. 1 illustrates an example of a schematic configuration of a solid-state imaging device 1 according to a first embodiment of the present disclosure. The solid-state imaging device 1 includes a pixel array section 10 in which a plurality of sensor pixels 11 is provided. In the pixel array section 10, the plurality of sensor pixels 11 is disposed two-dimensionally (in a matrix) at positions opposed to a light receiving surface 30A described below. The solid-state imaging device 1 further includes a peripheral circuit 20 that processes a pixel signal. The peripheral circuit 20 includes, for example, a vertical drive circuit 21, a column signal processing circuit 22, a horizontal drive circuit 23, and a system control circuit 24. The peripheral circuit 20 generates an output voltage on the basis of a pixel signal obtained from each of the sensor pixels 11 and outputs the output voltage to the outside.

For example, the vertical drive circuit 21 selects the plurality of sensor pixels 11 in order for each predetermined unit pixel row. The “predetermined unit pixel row” refers to a pixel row whose pixels are selectable by the same address. The column signal processing circuit 22 performs a correlated double sampling (Correlated Double Sampling: CDS) process, for example, on a pixel signal outputted from each of the sensor pixels 11 in a row selected by the vertical drive circuit 21. The column signal processing circuit 22 extracts the signal level of the pixel signal, for example, by performing the CDS process and holds pixel data corresponding to the amount of received light of each of the sensor pixels 11. The column signal processing circuit 22 includes, for example, a column signal processing section for each of data output lines VSL. The column signal processing section includes, for example, a single-slope A/D converter. The single-slope A/D converter includes, for example, a comparator and a counter circuit. The horizontal drive circuit 23 outputs, for example, the pieces of pixel data held in the column signal processing circuit 22 to outside in series. The system control circuit 24 controls, for example, the driving of the respective blocks (the vertical drive circuit 21, the column signal processing circuit 22, and the horizontal drive circuit 23) in the peripheral circuit 20.

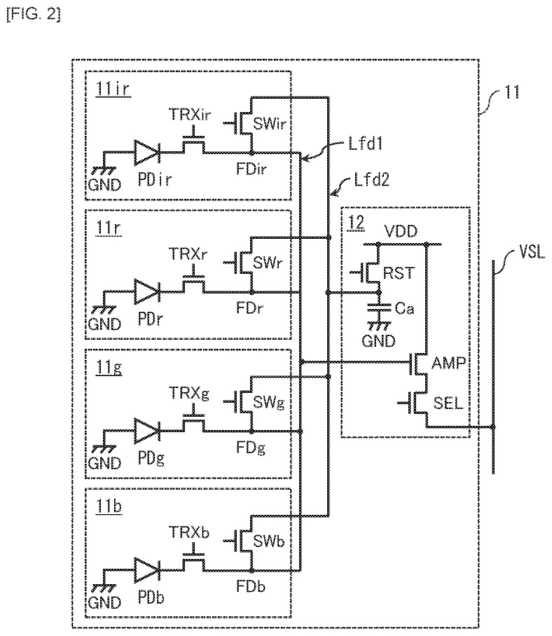

FIG. 2 illustrates an example of a circuit configuration of the sensor pixel 11. For example, as illustrated in FIG. 2, the sensor pixel 11 includes a plurality of photoelectric conversion elements PDir, PDr, PDg, and PDb having different wavelength selectivities. It is to be noted that the following uses the photoelectric conversion element PD as a generic term for the photoelectric conversion elements PDir, PDr, PDg, and PDb. The photoelectric conversion element PD corresponds to a specific example of a “photoelectric conversion section” according to the present disclosure. The photoelectric conversion element PD is an element that performs photoelectric conversion and generates electric charge corresponding to the amount of received light. The photoelectric conversion element PD is, for example, a photodiode. The sensor pixel 11 includes, for example, a pixel 11ir, a pixel 11r, a pixel 11g, and a pixel 11b. The pixel 11ir includes the photoelectric conversion element PDir. The pixel 11r includes the photoelectric conversion element PDr. The pixel 11g includes the photoelectric conversion element PDg. The pixel 11b includes the photoelectric conversion element PDb. The sensor pixel 11 further includes, for example, a pixel circuit 12 and wiring lines Lfd1 and Lfd2. The wiring lines Lfd1 and Lfd2 couple the respective pixels 11ir, 11r, 11g, and 11b and the pixel circuit 12. The wiring line Lfd1 is coupled to floating diffusions FDir, FDr, FDg, and FDb of the respective pixels 11ir, 11r, 11g, and 11b and coupled to the input end (the gate of an amplification transistor AMP) of the pixel circuit 12. The wiring line Lfd2 is coupled to the drains of switching transistors SWir, SWr, SWg, and SWb of the respective pixels 11ir, 11r, 11g, and 11b and coupled to the source (the terminal that is not coupled to a power supply line VDD) of a reset transistor RST in the pixel circuit 12. The pixel circuit 12 outputs a pixel signal based on electric charge outputted from each of the pixels 11ir, 11r, 11g, and 11b through the wiring line Lfd1. It is to be noted that the following uses the floating diffusion FD as a generic term for the floating diffusions FDir, FDr, FDg, and FDb. The floating diffusion FD corresponds to a specific example of an “electric charge holding section” according to the present disclosure. In addition, the following uses the switching transistor SW as a generic term for the switching transistors SWir, SWr, SWg, and SWb.

The pixel array section 10 includes the plurality of sensor pixels 11, a plurality of drive wiring lines, and the plurality of data output lines VSL. Each of the drive wiring lines is a wiring line to which a control signal is applied. The control signal is for controlling the output of the electric charges accumulated in the sensor pixel 11. The drive wiring line VOA extends, for example, in the row direction. The plurality of drive wiring lines is coupled, for example, to the output end of the vertical drive circuit 21. Each of the data output lines VSL is a wiring line for outputting a pixel signal outputted from each of the sensor pixels 11 to the peripheral circuit 20. The data output line VSL extends, for example, in the column direction. The data output line VSL is coupled, for example, to the output end of the pixel circuit 12.

For example, as illustrated in FIG. 2, the pixel 11ir includes the photoelectric conversion element PDir, a transfer transistor TRXir, the switching transistor SWir, and the floating diffusion FDir. In other words, the floating diffusion FDir is provided for each of the pixels 11ir. The transfer transistor TRXir is provided between the photoelectric conversion element PDir and the floating diffusion FDir. The cathode of the photoelectric conversion element PDir is coupled to the source of the transfer transistor TRXir and the anode of the photoelectric conversion element PDir is coupled to a reference potential line (e.g., ground GND). The drain of the transfer transistor TRXir is coupled to the floating diffusion FDir and the gate of the transfer transistor TRXir is coupled to a drive wiring line. The switching transistor SWir is provided between the source of the reset transistor RST of the pixel circuit 12 and the floating diffusion FDir. The drive wiring line is coupled to the gate of the switching transistor SWir.

The floating diffusion FDir is an impurity diffusion region that temporarily holds electric charge transferred from the photoelectric conversion element PDir. In a case where the transfer transistor TRXir is turned on, the transfer transistor TRXir transfers the electric charge of the photoelectric conversion element PDir to the floating diffusion FDir.

The switching transistor SWir is used to switch the conversion efficiency. In general, shooting in a dark place offers a small pixel signal. In a case where electric charge-voltage conversion is performed on the basis of Q=CV, the floating diffusion FDir having larger capacitance (FD capacitance C) results in smaller V that is obtained in a case of conversion to a voltage by the amplification transistor AMP described below. In contrast, shooting in a bright place offers a large pixel signal. It is therefore not possible for the floating diffusion FDir to sufficiently receive the electric charge of the photoelectric conversion element PDir unless the FD capacitance C is large. Further, the FD capacitance C has to be large to prevent V from being too large (i.e., to make V small) in a case of conversion to a voltage by the amplification transistor AMP. Taking these into consideration, in a case where the switching transistor SWir is turned on, the gate capacitance for the switching transistor SWir is increased. This causes the whole of the pixel 11ir to have the larger FD capacitance C. In contrast, in a case where the switching transistor SWir is turned off, the whole of the pixel 11ir has the smaller FD capacitance C. In this way, switching the switching transistor SWir on and off allows the whole of the pixel 11ir to have the variable FD capacitance C. This makes it possible to switch the conversion efficiency.

For example, as illustrated in FIG. 2, the pixel 11r includes the photoelectric conversion element PDr, a transfer transistor TRXr, the switching transistor SWr, and the floating diffusion FDr. In other words, the floating diffusion FDr is provided for each of the pixels 11r. The transfer transistor TRXr is provided between the photoelectric conversion element PDr and the floating diffusion FDr. The cathode of the photoelectric conversion element PDr is coupled to the source of the transfer transistor TRXr and the anode of the photoelectric conversion element PDr is coupled to a reference potential line (e.g., ground GND). The drain of the transfer transistor TRXr is coupled to the floating diffusion FDr and the gate of the transfer transistor TRXr is coupled to a drive wiring line. The switching transistor SWr is provided between the source of the reset transistor RST of the pixel circuit 12 and the floating diffusion FDr. The drive wiring line is coupled to the gate of the switching transistor SWr.

The floating diffusion FDr is an impurity diffusion region that temporarily holds electric charge transferred from the photoelectric conversion element PDr. In a case where the transfer transistor TRXr is turned on, the transfer transistor TRXr transfers the electric charge of the photoelectric conversion element PDr to the floating diffusion FDr. The switching transistor SWr is used to switch the conversion efficiency. In a case where the switching transistor SWr is turned on, the gate capacitance for the switching transistor SWr is increased. The whole of the pixel 11r has larger FD capacitance. In contrast, in a case where the switching transistor SWr is turned off, the whole of the pixel 11r has smaller FD capacitance.

For example, as illustrated in FIG. 2, the pixel 11g includes the photoelectric conversion element PDg, a transfer transistor TRXg, the switching transistor SWg, and the floating diffusion FDg. In other words, the floating diffusion FDg is provided for each of the pixels 11g. The transfer transistor TRXg is provided between the photoelectric conversion element PDg and the floating diffusion FDg. The cathode of the photoelectric conversion element PDg is coupled to the source of the transfer transistor TRXg and the anode of the photoelectric conversion element PDg is coupled to a reference potential line (e.g., ground GND). The drain of the transfer transistor TRXg is coupled to the floating diffusion FDg and the gate of the transfer transistor TRXg is coupled to a drive wiring line. The switching transistor SWg is provided between the source of the reset transistor RST of the pixel circuit 12 and the floating diffusion FDg. The drive wiring line is coupled to the gate of the switching transistor SWg.

The floating diffusion FDg is an impurity diffusion region that temporarily holds electric charge transferred from the photoelectric conversion element PDg. In a case where the transfer transistor TRXg is turned on, the transfer transistor TRXg transfers the electric charge of the photoelectric conversion element PDg to the floating diffusion FDg. The switching transistor SWg is used to switch the conversion efficiency. In a case where the switching transistor SWg is turned on, the gate capacitance for the switching transistor SWg is increased. The whole of the pixel 11g has larger FD capacitance. In contrast, in a case where the switching transistor SWg is turned off, the whole of the pixel 11g has smaller FD capacitance.

For example, as illustrated in FIG. 2, the pixel 11b includes the photoelectric conversion element PDb, a transfer transistor TRXb, the switching transistor SWb, and the floating diffusion FDb. In other words, the floating diffusion FDb is provided for each of the pixels 11b. The transfer transistor TRXb is provided between the photoelectric conversion element PDb and the floating diffusion FDb. The cathode of the photoelectric conversion element PDb is coupled to the source of the transfer transistor TRXb and the anode of the photoelectric conversion element PDb is coupled to a reference potential line (e.g., ground GND). The drain of the transfer transistor TRXb is coupled to the floating diffusion FDb and the gate of the transfer transistor TRXb is coupled to a drive wiring line. The switching transistor SWb is provided between the source of the reset transistor RST of the pixel circuit 12 and the floating diffusion FDb. The drive wiring line is coupled to the gate of the switching transistor SWb.

The floating diffusion FDb is an impurity diffusion region that temporarily holds electric charge transferred from the photoelectric conversion element PDb. In a case where the transfer transistor TRXb is turned on, the transfer transistor TRXb transfers the electric charge of the photoelectric conversion element PDb to the floating diffusion FDb. The switching transistor SWb is used to switch the conversion efficiency. In a case where the switching transistor SWb is turned on, the gate capacitance for the switching transistor SWb is increased. The whole of the pixel 11b has larger FD capacitance. In contrast, in a case where the switching transistor SWb is turned off, the whole of the pixel 11b has smaller FD capacitance.

As illustrated in FIG. 2, the pixel circuit 12 includes, for example, the reset transistor RST, a capacitor Ca, a selection transistor SEL, and the amplification transistor AMP. The source of the reset transistor RST is coupled to the capacitor Ca and coupled to the switching transistors SWir, SWr, SWg, and SWb through the wiring line Lfd2. The capacitor Ca is provided between the source of the reset transistor RST and a reference potential line (e.g., ground GND). In other words, in a case where the reset transistor RST is off, the terminals of the switching transistors SWir, SWr, SWg, and SWb on the reset transistor RST side are floating. The drain of the reset transistor RST is coupled to the power supply line VDD and the drain of the amplification transistor AMP. The gate of the reset transistor RST is coupled to the vertical drive circuit 21 through a drive wiring line. The source of the amplification transistor AMP is coupled to the drain of the selection transistor SEL and the gate of the amplification transistor AMP is coupled to the floating diffusions FDir, FDr, FDg, and FD through the wiring line Lfd1. The source of the selection transistor SEL is coupled to the column signal processing circuit 22 through the data output line VSL and the gate of the selection transistor SEL is coupled to the vertical drive circuit 21 through a drive wiring line.

The reset transistor RST resets the potential of the floating diffusion FD to a predetermined potential. In a case where the reset transistor RST and the switching transistor SW are turned on, the potential of the floating diffusion FD is reset to the potential of the power supply line VDD. The selection transistor SEL controls the output timing of a pixel signal from the pixel circuit 12. The amplification transistor AMP generates, as a pixel signal, a signal of the voltage corresponding to the level of the electric charge held in the floating diffusion FD. The amplification transistor AMP is included in an amplifier of a source follower type and outputs a pixel signal of the voltage corresponding to the level of the electrical charge generated in the photoelectric conversion element PD. In a case where the selection transistor SEL is turned on, the amplification transistor AMP amplifies the potential of the floating diffusion FD and outputs the voltage corresponding to the potential to the column signal processing circuit 22 through the data output line VSL.

The transfer transistors TRXir, TRXr, RTXg, and TRXb, the switching transistors SWir, SWr, SWg, and SWb, the reset transistor RST, the amplification transistor AMP, and the selection transistor SEL are, for example, NMOS transistors. It is to be noted that the following uses the transfer transistor TRX as a generic term for the transfer transistors TRXir, TRXr, RTXg, and TRXb.

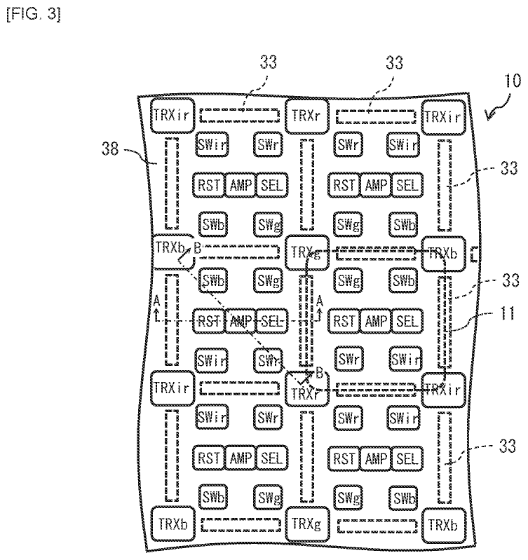

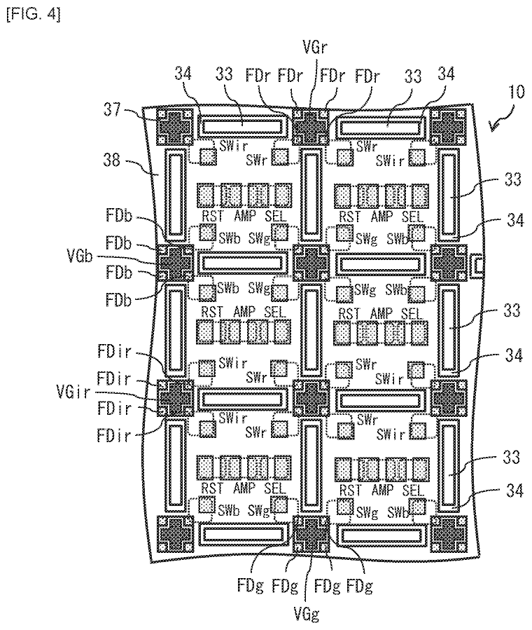

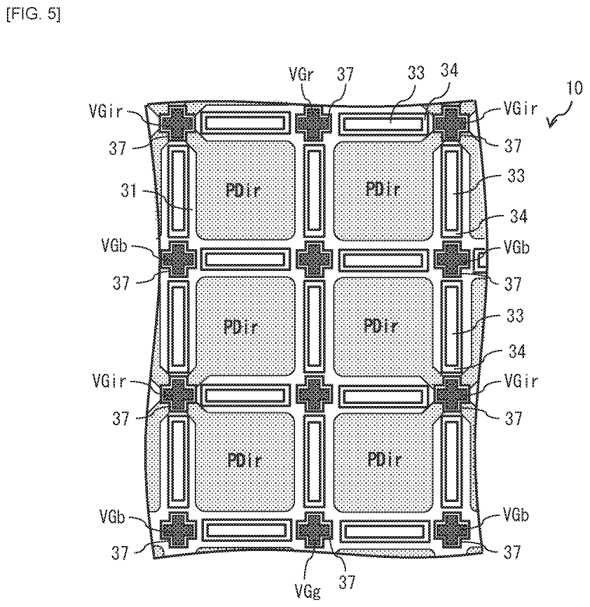

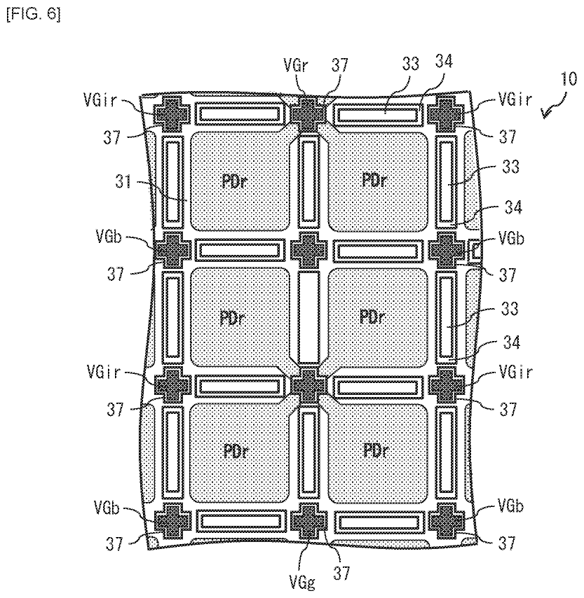

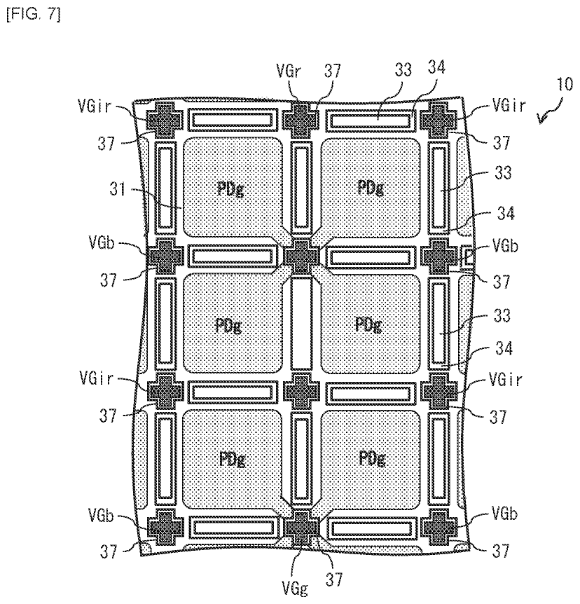

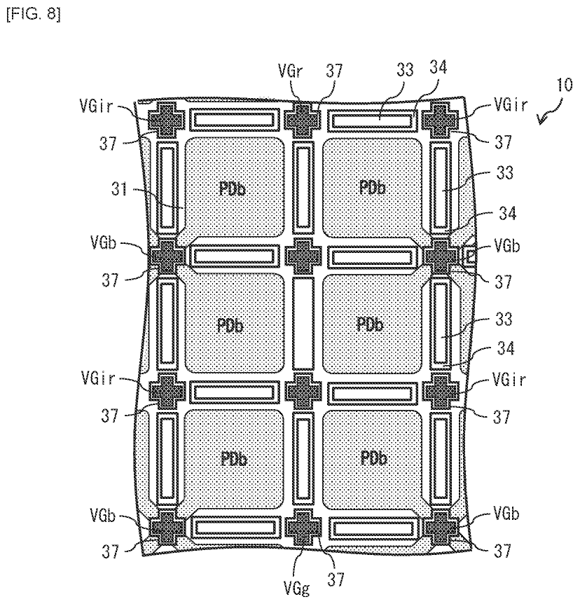

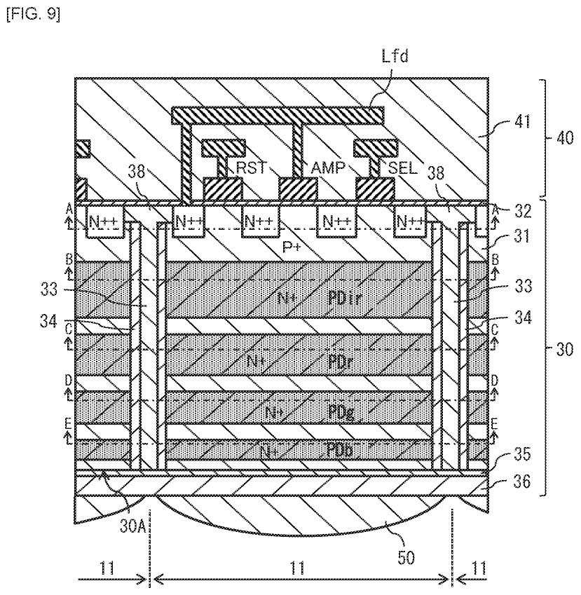

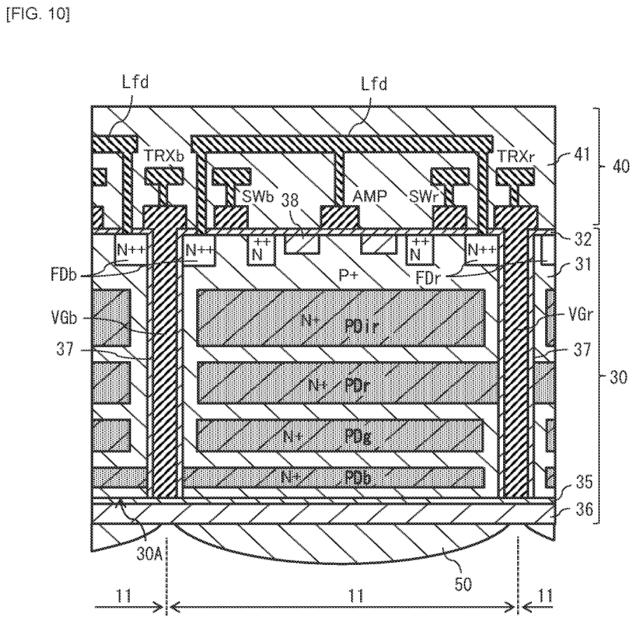

Next, a planar configuration and a cross-sectional configuration of the pixel array section 10 are described. FIG. 3 illustrates an example of a planar configuration of the pixel array section 10. Each of FIGS. 4, 5, 6, 7, and 8 illustrates an example of a horizontal cross-sectional configuration of the pixel array section 10. Each of FIGS. 9 and 10 illustrates an example of a vertical cross-sectional configuration of the pixel array section 10. FIG. 3 illustrates an example of a planar layout of the respective components other than the wiring lines Lfd1 and Lfd2 in the pixel array section 10 as viewed from a wiring layer 40 side described below. The wiring lines Lfd1 and Lfd2 are described below. FIG. 4 illustrates an example of a cross-sectional configuration taken along the A-A line in FIG. 9. FIG. 5 illustrates an example of a cross-sectional configuration taken along the B-B line in FIG. 9. FIG. 6 illustrates an example of a cross-sectional configuration taken along the C-C line in FIG. 9. FIG. 7 illustrates an example of a cross-sectional configuration taken along the D-D line in FIG. 9. FIG. 8 illustrates an example of a cross-sectional configuration taken along the E-E line in FIG. 9. FIG. 9 illustrates an example of a cross-sectional configuration taken along the A-A line in FIG. 3. FIG. 10 illustrates an example of a cross-sectional configuration taken along the B-B line in FIG. 3.

For example, the sensor pixels 11 each include a stacked photoelectric conversion element in which the plurality of photoelectric conversion elements PDir, PDr, PDg, and PDb is stacked. The plurality of photoelectric conversion elements PDir, PDr, PDg, and PDb has different wavelength selectivities. In other words, the solid-state imaging device 1 includes the stacked photoelectric conversion element described above for each of the sensor pixels 11. The sensor pixel 11 further includes an on-chip lens 50 at a portion opposed to the stacked photoelectric conversion element described above. In other words, the solid-state imaging device 1 includes the on-chip lens 50 for each of the sensor pixels 11.

The plurality of photoelectric conversion elements PDir, PDr, PDg, and PDb is formed in a semiconductor layer 31 described below. The semiconductor layer 31 includes, for example, a p-type silicon (Si) layer. Each of the photoelectric conversion elements PDir, PDr, PDg, and PDb includes, for example, an n-type silicon layer. An electric field is formed between the n-type silicon layer used to form the photoelectric conversion element PD and the p-type silicon layer used to form the semiconductor layer 31. This holds the electric charge of each of the photoelectric conversion elements PDir, PDr, PDg, and PDb.

The photoelectric conversion element PDir is formed at a position (depth) apart from the light receiving surface 30A (described below) of the semiconductor layer 31. The photoelectric conversion element PDir includes a material having sensitivity to near-infrared light having a wavelength of 850 nm to infrared light having a wavelength of about 2 μm. The photoelectric conversion element PDr is formed at a position (depth) in the semiconductor layer 31 apart from the light receiving surface 30A and closer to the light receiving surface 30A than the photoelectric conversion element PDir. The photoelectric conversion element PDr includes a material having sensitivity to red light (light in a wavelength range of 620 nm or more and 750 nm or less). The photoelectric conversion element PDg is formed at a position (depth) in the semiconductor layer 31 apart from the light receiving surface 30A and closer to the light receiving surface 30A than the photoelectric conversion element PDr. The photoelectric conversion element PDr includes a material having sensitivity to green light (light in a wavelength range of 495 nm or more and 570 nm or less). The photoelectric conversion element PDb is formed at a position in the semiconductor layer 31 between the light receiving surface 30A and the photoelectric conversion element PDg. The photoelectric conversion element PDb includes a material having sensitivity to blue light (light in a wavelength range of 425 nm or more and 495 nm or less).

For example, as illustrated in FIGS. 9 and 10, the pixel array section 10 includes a light receiving substrate 30 and the wiring layer 40 that are stacked. The plurality of on-chip lenses 50 is bonded to the surface of the light receiving substrate 30 opposite to the wiring layer 40. The light receiving substrate 30 includes, for example, the semiconductor layer 31, a fixed electric charge film 35, and an anti-reflection film 36. The fixed electric charge film 35 and the anti-reflection film 36 are provided in the semiconductor layer 31 on the on-chip lens 50 side. In the semiconductor layer 31, the plurality of photoelectric conversion elements PDir, PDr, PDg, and PDb is formed. The plurality of photoelectric conversion elements PDir, PDr, PDg, and PDb has different depths from the surface (light receiving surface 30A) on the on-chip lens 50 side and each photoelectrically converts light coming through the light receiving surface 30A.

The fixed electric charge film 35 has negative fixed electric charge to suppress the generation of dark currents due to the interface state of the semiconductor layer 31 on the light receiving surface 30A. The fixed electric charge film 35 is formed by using, for example, an insulating film having negative fixed electric charge. Examples of a material of such an insulating film include hafnium oxide, zirconium oxide, aluminum oxide, titanium oxide, or tantalum oxide. An electric field induced by the fixed electric charge film 35 forms a hole accumulation layer on the light receiving surface 30A. This hole accumulation layer suppresses the generation of electrons from the light receiving surface 30A. The anti-reflection film 36 is formed, for example, in contact with the fixed electric charge film 35. The anti-reflection film 36 suppresses the reflection of light entering the photoelectric conversion element PD and efficiently allows light to reach the photoelectric conversion element PD. The anti-reflection film 36 includes, for example, at least one of silicon oxide, silicon nitride, aluminum oxide, hafnium oxide, zirconium oxide, tantalum oxide, or titanium oxide.

The pixels 11ir, 11r, 11g, and 11b and the pixel circuit 12 (the reset transistor RST, the selection transistor SEL, and the amplification transistor AMP) are formed for each of the sensor pixels 11 on the surface of the semiconductor layer 31 on the wiring layer 40 side. The pixels 11ir, 11r, 11g, and 11b do not include the photoelectric conversion elements PDir, PDr, PDg, and PDb.

The surface of the semiconductor layer 31 on the wiring layer 40 side includes, for example, an insulating film 32 that is used as a gate oxide film of a variety of transistors (the transfer transistors TRXir, TRXr, RTXg, and TRXb, the switching transistors SWir, SWr, SWg, and SWb, the reset transistor RST, the selection transistor SEL, and the amplification transistor AMP). The insulating film 32 is a silicon oxide film formed by performing, for example, thermal oxidation or the like on a surface of a silicon layer.

The wiring layer 40 is provided with the gate electrodes of the variety of transistors (the transfer transistors TRXir, TRXr, RTXg, and TRXb, the switching transistors SWir, SWr, SWg, and SWb, the reset transistor RST, the selection transistor SEL, and the amplification transistor AMP), the wiring lines Lfd1 and Lfd2, and the like. The gate electrodes of the variety of transistors, the wiring lines Lfd1 and Lfd2, and the like are provided in an insulating layer 41. The gate electrodes of the variety of transistors are provided in contact with the insulating film 32 used as a gate oxide film. The wiring line Lfd1 is in contact with the plurality of floating diffusions FDir, FDr, FDg, and FDb included in the sensor pixel 11 and the gate of the amplification transistor AMP through an opening provided in the insulating film 32. The wiring line Lfd2 is in contact with the drain of the switching transistor SW and the source of the reset transistor RST through the opening provided in the insulating film 32.

The transfer transistors TRXir, TRXr, RTXg, and TRXb include vertical gate electrodes VGir, VGr, VGg, and VGb as gate electrodes. Portions of the vertical gate electrodes VGir, VGr, VGg, and VGb other than the upper ends (umbrella-shaped portions) are formed in the semiconductor layer 31 to extend in the thickness direction of the semiconductor layer 31. In other words, the transfer transistors TRXir, TRXr, RTXg, and TRXb are vertical transistors. The lower end of the vertical gate electrode VGir is formed, for example, at the depth that allows the lower end of the vertical gate electrode VGir to reach at least the photoelectric conversion element PDir. The lower end of the vertical gate electrode VGr is formed, for example, at the depth that allows the lower end of the vertical gate electrode VGr to reach at least the photoelectric conversion element PDr. The lower end of the vertical gate electrode VGg is formed, for example, at the depth that allows the lower end of the vertical gate electrode VGg to reach at least the photoelectric conversion element PDg. The lower end of the vertical gate electrode VGb is formed, for example, at the depth that allows the lower end of the vertical gate electrode VGb to reach at least the photoelectric conversion element PDb.

Each of the vertical gate electrodes VGir, VGr, VGg, and VGb is formed by filling, for example, a trench provided in the semiconductor layer 31 and having the inner wall covered with the insulating film 32, for example, with a metal material or an electrically conductive material such as polysilicon. The insulating film 32 in the trench is formed by performing, for example, thermal oxidation or the like on the inner wall of the trench provided in the silicon layer. The trench is filled with an electrically conductive material, for example, by CVD (Chemical Vapor Deposition) or the like. It is to be noted that each of FIGS. 4 to 8 and 10 illustrates an example in which the semiconductor layer 31 is provided with through trenches and the vertical gate electrodes VGir, VGr, VGg, and VGb are provided in these through trenches. The vertical gate electrodes VGir, VGr, VGg, and VGb extend to the depth that allows the vertical gate electrodes VGir, VGr, VGg, and VGb to penetrate the semiconductor layer 31.

The pixel array section 10 further includes an element separator 33 that defines the respective sensor pixels 11, for example, as illustrated in FIGS. 3 to 9. The element separator 33 is formed at least closer to the surface of the semiconductor layer 31 opposite to the light receiving surface 30A. The element separator 33 extends in the semiconductor layer 31 in the thickness direction of the semiconductor layer 31. For example, as illustrated in FIG. 9, the element separator 33 is formed to penetrate the semiconductor layer 31. The element separator 33 electrically separates the two sensor pixels 11 adjacent to each other closer to at least the surface of the semiconductor layer 31 opposite to the light receiving surface 30A. For example, as illustrated in FIGS. 3 to 9, the element separator 33 is provided at the border between the two sensor pixels 11 adjacent to each other in a plan view. The element separator 33 is further provided at a portion other than the border between the four sensor pixels 11 adjacent to each other in a plan view. The element separator 33 includes, for example, silicon oxide. The element separator 33 may include, for example, the two layers of polysilicon and silicon oxide.

For example, as illustrated in FIG. 9, the pixel array section 10 further includes a well layer 34 that is in contact with a side surface of the element separator 33. The well layer 34 includes a semiconductor region having an electrical conduction type (e.g., p type) different from that of the photoelectric conversion element PD. For example, as illustrated in FIGS. 3, 4, 9, and 10, the pixel array section 10 further includes a separator 38 on and near the surface of the semiconductor layer 31 opposite to the light receiving surface 30A in each of the sensor pixels 11. The separator 38 separates the respective transfer transistors TRX, the respective switching transistors SW, and the pixel circuit 12 from each other. The separator 38 includes the upper end of the element separator 33. The separator 38 includes, for example, silicon oxide.

Next, the disposition of the transfer transistors TRX is described. The transfer transistors TRXir, TRXr, RTXg, and TRXb are disposed along the border between the two or four sensor pixels 11 adjacent to each other in a plan view. This border corresponds, for example, to a dashed line represented by the sign “11” in FIG. 3. For example, as illustrated in FIGS. 3 to 8 and 10, the transfer transistors TRXir, TRXr, RTXg, and TRXb are disposed side by side at the border between the two or four sensor pixels 11 adjacent to each other in a plan view. For example, as illustrated in FIGS. 3 to 8 and 10, the transfer transistors TRXir, TRXr, RTXg, and TRXb are disposed at the border between the four sensor pixels 11 adjacent to each other in a plan view.

In this case, the vertical gate electrode VGir of the transfer transistor TRXir is shared between the four sensor pixels 11 that form the border of a portion at which the transfer transistor TRXir is disposed. In addition, the vertical gate electrode VGr of the transfer transistor TRXr is shared between the four sensor pixels 11 that form the border of a portion at which the transfer transistor TRXr is disposed. In addition, the vertical gate electrode VGg of the transfer transistor TRXg is shared between the four sensor pixels 11 that form the border of a portion at which the transfer transistor TRXg is disposed. In addition, the vertical gate electrode VGb of the transfer transistor TRXb is shared between the four sensor pixels 11 that form the border of a portion at which the transfer transistor TRXb is disposed. FIG. 10 illustrates an example in which the vertical gate electrode VGb is shared between the two sensor pixels 11 adjacent to each other and the vertical gate electrode VGr is shared between the two sensor pixels 11 adjacent to each other.

Each of the transfer transistors TRXir is provided with an equal number of (four) floating diffusions FDir to the number of sensor pixels 11 that share the transfer transistor TRXir. In each of the transfer transistors TRXir, the four floating diffusions FDir are assigned to the four respective sensor pixels 11 adjacent to each other one by one. Similarly, each of the transfer transistors TRXr is provided with an equal number of (four) floating diffusions FDr to the number of sensor pixels 11 that share the transfer transistor TRXr. In each of the transfer transistors TRXr, the four floating diffusions FDr are assigned to the four respective sensor pixels 11 adjacent to each other one by one.

In addition, each of the transfer transistors TRXg is provided with an equal number of (four) floating diffusions FDr to the number of sensor pixels 11 that share the transfer transistor TRXg. In each of the transfer transistors TRXg, the four floating diffusions FDg are assigned to the four respective sensor pixels 11 adjacent to each other one by one. In addition, each of the transfer transistors TRXb is provided with an equal number of (four) floating diffusions FDr to the number of sensor pixels 11 that share the transfer transistor TRXb. In each of the transfer transistors TRXb, the four floating diffusions FDb are assigned to the four respective sensor pixels 11 adjacent to each other one by one.

For example, as illustrated in FIGS. 4 to 8, the horizontal cross-sectional shape of a vertical gate electrode VG is a cross shape along the border in each of the transfer transistors TRX. In this case, the four floating diffusions FD are disposed, for example, in the four dents of the cross shape of the vertical gate electrode VG in each of the transfer transistors TRX. It is to be noted that the horizontal cross-sectional shape of the vertical gate electrode VG is not limited to a cross shape.

In the four sensor pixels 11 that share the vertical gate electrode VGir of the transfer transistor TRXir, the respective photoelectric conversion elements PDir are in contact with the vertical gate electrode VGir through an insulating film 37, for example, as illustrated in FIG. 5. In addition, the respective photoelectric conversion elements PDir are in contact with the other photoelectric conversion elements PDir through the semiconductor layer 31 (p-type silicon layer). In other words, the semiconductor layer 31 (p-type silicon layer) is formed between the two photoelectric conversion elements PDir adjacent to each other. Further, the semiconductor layer 31 (p-type silicon layer) is formed between the vertical gate electrode VGir of the transfer transistor TRXir and the element separator 33. This electrically separates each of the photoelectric conversion elements PDir from the other adjacent photoelectric conversion elements PDir by the semiconductor layer 31 (p-type silicon layer).

In addition, the four sensor pixels 11 that share the vertical gate electrode VGr of the transfer transistor TRXr, the respective photoelectric conversion elements PDr are in contact with the vertical gate electrode VGr through the insulating film 37, for example, as illustrated in FIG. 6. In addition, the respective photoelectric conversion elements PDr are in contact with the other photoelectric conversion elements PDr through the semiconductor layer 31 (p-type silicon layer). In other words, the semiconductor layer 31 (p-type silicon layer) is formed between the two photoelectric conversion elements PDr adjacent to each other. Further, the semiconductor layer 31 (p-type silicon layer) is formed between the vertical gate electrode VGr of the transfer transistor TRXr and the element separator 33. This electrically separates each of the photoelectric conversion elements PDr from the other adjacent photoelectric conversion elements PDr by the semiconductor layer 31 (p-type silicon layer).

In addition, the four sensor pixels 11 that share the vertical gate electrode VGg of the transfer transistor TRXg, the four photoelectric conversion elements PDg are in contact with the vertical gate electrode VGg through the insulating film 37, for example, as illustrated in FIG. 7. In addition, the four photoelectric conversion elements PDg are in contact with the other photoelectric conversion elements PDg through the semiconductor layer 31 (p-type silicon layer). In other words, the semiconductor layer 31 (p-type silicon layer) is formed between the two photoelectric conversion elements PDg adjacent to each other. Further, the semiconductor layer 31 (p-type silicon layer) is formed between the vertical gate electrode VGg of the transfer transistor TRXg and the element separator 33. This electrically separates each of the photoelectric conversion elements PDg from the other adjacent photoelectric conversion elements PDg by the semiconductor layer 31 (p-type silicon layer).

In addition, the four sensor pixels 11 that share the vertical gate electrode VGb of the transfer transistor TRXb, the four photoelectric conversion elements PDb are in contact with the vertical gate electrode VGb through the insulating film 37, for example, as illustrated in FIG. 8. In addition, the four photoelectric conversion elements PDb are in contact with the other photoelectric conversion elements PDb through the semiconductor layer 31 (p-type silicon layer). In other words, the semiconductor layer 31 (p-type silicon layer) is formed between the two photoelectric conversion elements PDb adjacent to each other. Further, the semiconductor layer 31 (p-type silicon layer) is formed between the vertical gate electrode VGb of the transfer transistor TRXb and the element separator 33. This electrically separates each of the photoelectric conversion elements PDb from the other adjacent photoelectric conversion elements PDb by the semiconductor layer 31 (p-type silicon layer).

[Operation]

Next, an operation of the solid-state imaging device 1 according to the present embodiment is described.

In the four sensor pixels 11 that share the vertical gate electrode VG of the transfer transistor TRX, the electric charge accumulated in the photoelectric conversion element PD of the one sensor pixel 11 (referred to as “first sensor pixel 11” below) is transferred to the floating diffusion FD through the side wall of the vertical gate electrode VG on the first sensor pixel 11 side by turning on the transfer transistor TRX. Similarly, in the four sensor pixels 11 that share the vertical gate electrode VG of the transfer transistor TRX, the electric charge accumulated in the photoelectric conversion element PD of the sensor pixel 11 (referred to as “second sensor pixel 11” below) different from the first sensor pixel 11 is transferred to the floating diffusion FD through the side wall of the vertical gate electrode VG on the second sensor pixel 11 side by turning on the transfer transistor TRX. In this way, in each of the sensor pixels 11 that share the vertical gate electrode VG of the transfer transistor TRX, the electric charge accumulated in the photoelectric conversion element PD is transferred to the corresponding floating diffusion FD.

The electric charge transferred to the floating diffusion FD is amplified by the amplification transistor AMP and outputted to the data output line VSL as a pixel signal. The signal level of the pixel signal is detected by the column signal processing circuit 22 and the resultant detection value is outputted to the outside as pixel data.

Incidentally, the electric charge accumulated in the respective photoelectric conversion elements PD is transferred to the corresponding floating diffusions FD concurrently in a case where the transfer transistor TRX is turned on. In this case, the electric charge accumulated in each of the photoelectric conversion elements PD is not transferred to the floating diffusion FD different from the corresponding floating diffusion FD. This is because the semiconductor layer 31 (p-type silicon layer) having an electrical conduction type different from the electrical conduction type (e.g., n type) of the photoelectric conversion element PD is present between the transfer transistor TRX (vertical gate electrode VG) and the element separator 33, for example, as illustrated in FIG. 5 and a potential barrier is formed between the semiconductor layer 31 (p-type silicon layer) present between the transfer transistor TRX and the element separator 33 and the vertical gate electrode VG. In other words, the four floating diffusions FD that share the vertical gate electrode VG are separated from each other by the semiconductor layer 31 (p-type silicon layer). It is to be noted that, in a case where the horizontal cross-sectional shape of the transfer transistor TRX is the cross shape as illustrated in FIG. 5, an electric field concentrates on the dents of the cross shape and is easier to modulate.

[Effects]

Next, effects of the solid-state imaging device 1 according to the present embodiment are described.

Methods are developed of dispersing light by forming a plurality of photodiodes per pixel in a substrate in the depth direction to prevent the solid-state imaging device from having a false color (see, for example, PTL 1).

Incidentally, in the solid-state imaging device described above, the electric charge obtained by each of the photodiodes is transferred to a floating diffusion through a vertical transistor. The electric charge of light entering each of the pixels resulting from photoelectric conversion in the vertical transistor is, however, difficult for a photodiode to absorb. This may decrease the sensitivity.

In contrast, in the present embodiment, a plurality of vertical transistors (the plurality of transfer transistors TRX) provided in the respective sensor pixels 11 is disposed along the border between the two or four sensor pixels 11 adjacent to each other. This makes it possible to decrease the proportion of light entering each sensor pixel 11 that is photoelectrically converted by the respective transfer transistors TRX as compared with the proportion of light that is photoelectrically converted by the respective transfer transistors TRX disposed near the middle of each sensor pixel 11. As a result, it is possible to suppress a decrease in sensitivity. In addition, in the present embodiment, a plurality of vertical transistors (the plurality of transfer transistors TRX) is disposed at corners of the sensor pixel 11. This makes it possible to prevent the plurality of vertical transistors (the plurality of transfer transistors TRX) from blocking light entering the photoelectric conversion element PD. As a result, it is possible to reduce the grazing incidence characteristic distortion.

In addition, in the present embodiment, each of the sensor pixels 11 is provided with the four transfer transistors TRX. The four transfer transistors TRX are provided at the border between the four sensor pixels 11 adjacent to each other. This makes it possible to decrease the proportion of light entering each sensor pixel 11 that is photoelectrically converted by the respective transfer transistors TRX as compared with the proportion of light that is photoelectrically converted by the respective transfer transistors TRX disposed near the middle of each sensor pixel 11. As a result, it is possible to suppress a decrease in sensitivity. In this case, the element separator 33 is provided at the border between the two sensor pixels 11 adjacent to each other. The semiconductor layer 31 (p-type silicon layer) having an electrical conduction type different from the electrical conduction type (e.g., n type) of the photoelectric conversion element PD is present between the transfer transistors TRX and the element separator 33. In a case where the electric charge accumulated in the respective photoelectric conversion elements PD is concurrently transferred to the corresponding floating diffusions FD, this prevents the electric charge from being transferred to the floating diffusion FD different from the corresponding floating diffusion FD. As a result, it is possible to suppress a decrease in sensitivity caused by the transfer leakage of electric charge.

<2. Modification Examples of First Embodiment>

Next, modification examples of the solid-state imaging device 1 according to the embodiment described above are described.

[Modification Example A]

In the embodiment described above, the one pixel circuit 12 and the one data output line VSL are provided for the four pixels 11ir, 11r, 11b, and 11g. However, for example, as illustrated in FIG. 11, the pixel 11ir, the data output line VSL, the amplification transistor AMP, and the selection transistor SEL may be omitted and two pixel circuits 12a and 12b may be provided for the three pixels 11r, 11b, and 11g and a data output line VSL1 and a data output line VSL2 may be respectively provided for the pixel circuit 12a and the pixel circuit 12b.

The pixel circuit 12a is provided for the two pixels 11r and 11b. The pixel circuit 12a may include, for example, an amplification transistor AMP1 and a selection transistor SELL Further, the pixel circuit 12b is provided for the one pixel 11g. The pixel circuit 12b may include, for example, an amplification transistor AMP2 and a selection transistor SEL2. Each of the amplification transistors AMP1 and AMP2 has a configuration similar to that of the amplification transistor AMP. The output end of the pixel circuit 12a is coupled to the data output line VSL1 and the output end of the pixel circuit 12b is coupled to the data output line VSL2 different from the data output line VSL1.

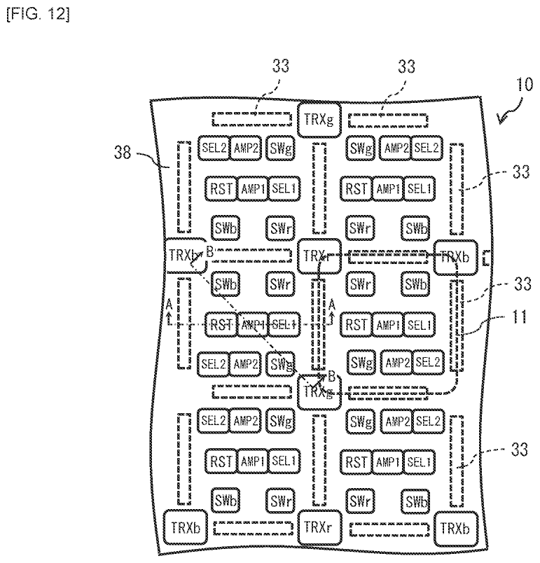

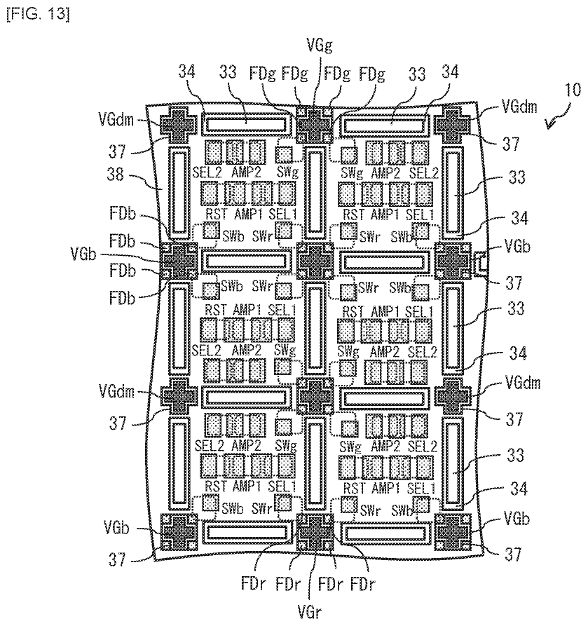

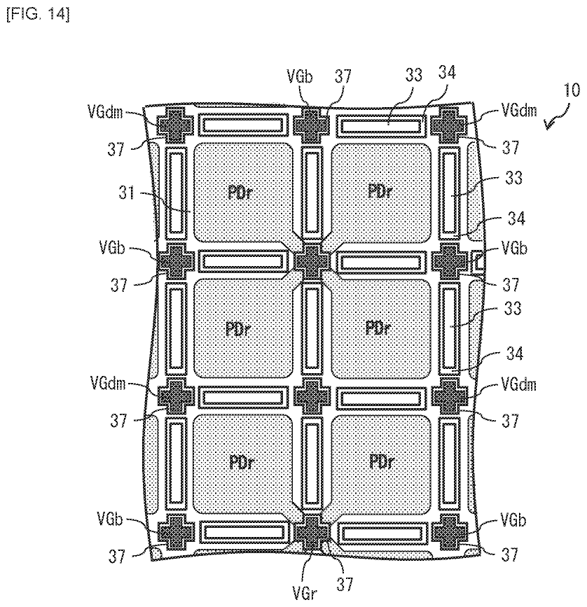

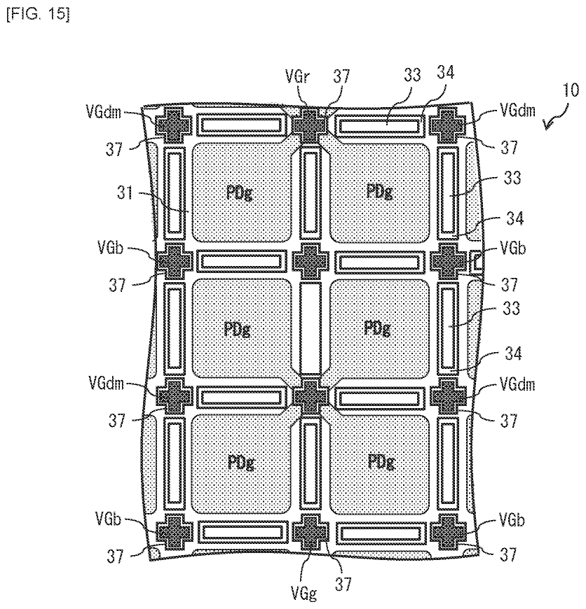

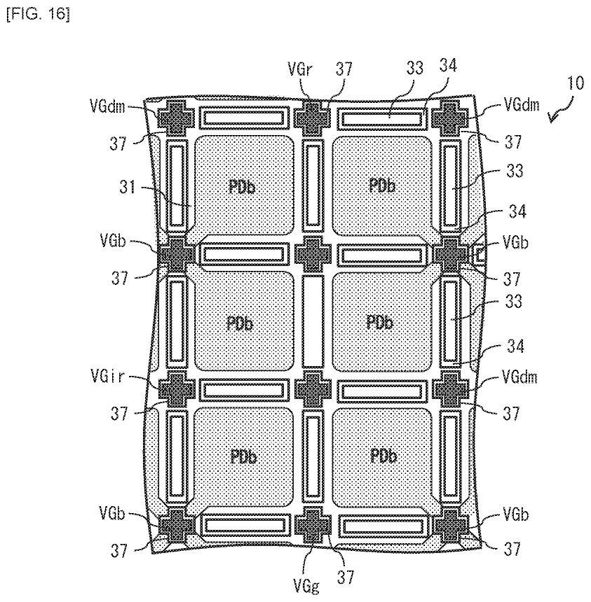

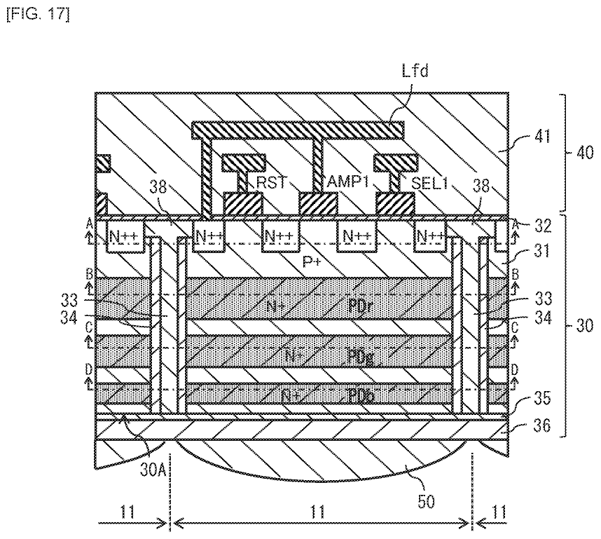

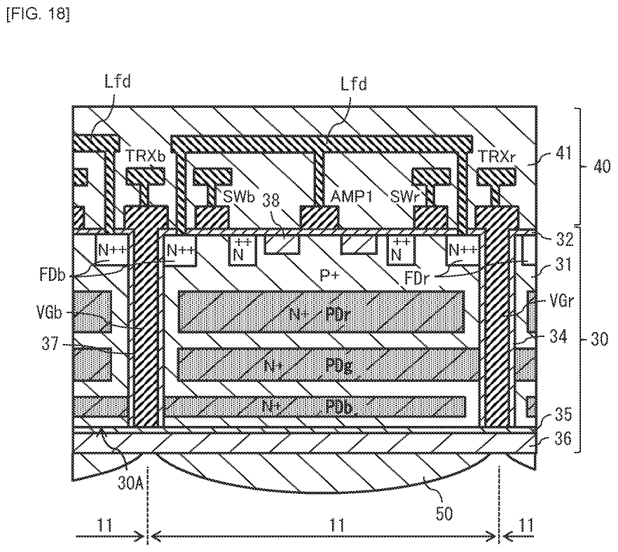

Next, a planar configuration and a cross-sectional configuration of the pixel array section 10 according to the present modification example are described. FIG. 12 illustrates an example of a planar configuration of the pixel array section 10. Each of FIGS. 13, 14, 15, and 16 illustrates an example of a horizontal cross-sectional configuration of the pixel array section 10. Each of FIGS. 17 and 18 illustrates an example of a vertical cross-sectional configuration of the pixel array section 10. FIG. 12 illustrates an example of a planar layout of the respective components other than the wiring lines Lfd1 and Lfd2 in the pixel array section 10 as viewed from the wiring layer 40 side. FIG. 13 illustrates an example of a cross-sectional configuration taken along the A-A line in FIG. 17. FIG. 14 illustrates an example of a cross-sectional configuration taken along the B-B line in FIG. 17. FIG. 15 illustrates an example of a cross-sectional configuration taken along the C-C line in FIG. 17. FIG. 16 illustrates an example of a cross-sectional configuration taken along the D-D line in FIG. 17. FIG. 17 illustrates an example of a cross-sectional configuration taken along the A-A line in FIG. 12. FIG. 18 illustrates an example of a cross-sectional configuration taken along the B-B line in FIG. 12. It is to be noted that the descriptions of the components similar to those of the embodiment described above are omitted as appropriate.

In the present modification example, for example, as illustrated in FIGS. 12 to 18, the photoelectric conversion element PDir, the transfer transistor TRXir, the floating diffusion FDir, and the switching transistor SWir included in the pixel 11ir according to the embodiment described above are omitted. Further, in the present modification example, for example, as illustrated in FIGS. 12, 13, 17, and 18, the amplification transistor AMP1 for the pixels 11r and 11b and the amplification transistor AMP2 for the pixel 11g are provided instead of the amplification transistor AMP for the pixels 11r, 11g, and 11b.

In the present modification example, for example, as illustrated in FIGS. 13 to 16, there is provided a dummy electrode VGdm at a portion at which the vertical gate electrode VGir of the transfer transistor TRXir according to the embodiment described above is provided. The dummy electrode VGdm is electrically separated from the sensor pixel 11. The presence or absence of the dummy electrode VGdm is not thus directly related to the transfer of electric charge. The dummy electrode VGdm may be therefore omitted as appropriate.

Next, an operation of the solid-state imaging device 1 according to the present modification example is described.

In the four sensor pixels 11 that share the vertical gate electrode VG of the transfer transistor TRX, the electric charge accumulated in the photoelectric conversion element PD of the one sensor pixel 11 (referred to as “first sensor pixel 11” below) is transferred to the floating diffusion FD through the side wall of the vertical gate electrode VG on the first sensor pixel 11 side by turning on the transfer transistor TRX. Similarly, in the four sensor pixels 11 that share the vertical gate electrode VG of the transfer transistor TRX, the electric charge accumulated in the photoelectric conversion element PD of the sensor pixel 11 (referred to as “second sensor pixel 11” below) different from the first sensor pixel 11 is transferred to the floating diffusion FD through the side wall of the vertical gate electrode VG on the second sensor pixel 11 side by turning on the transfer transistor TRX. In this way, in each of the sensor pixels 11 that share the vertical gate electrode VG of the transfer transistor TRX, the electric charge accumulated in the photoelectric conversion element PD is transferred to the corresponding floating diffusion FD.

The electric charge transferred to each of the floating diffusions FDr and FDb is amplified by the amplification transistor AMP1 and outputted to the data output line VSL1 as a pixel signal. The electric charge transferred to the floating diffusion FDg is amplified by the amplification transistor AMP2 and outputted to the data output line VSL2 as a pixel signal. The signal level of the pixel signal is detected by the column signal processing circuit 22 and the resultant detection value is outputted to the outside as pixel data.

Next, effects of the solid-state imaging device 1 according to the present modification example are described.

In the present modification example, as in the embodiment described above, a plurality of vertical transistors (the plurality of transfer transistors TRX) provided in the respective sensor pixels 11 is disposed along the border between the two or four sensor pixels 11 adjacent to each other. This makes it possible to decrease the proportion of light entering each sensor pixel 11 that is photoelectrically converted by the respective transfer transistors TRX as compared with the proportion of light that is photoelectrically converted by the respective transfer transistors TRX disposed near the middle of each sensor pixel 11. As a result, it is possible to suppress a decrease in sensitivity. In addition, in the present modification example, a plurality of vertical transistors (the plurality of transfer transistors TRX) is disposed at corners of the sensor pixel 11. This makes it possible to prevent the plurality of vertical transistors (the plurality of transfer transistors TRX) from blocking light entering the photoelectric conversion element PD. As a result, it is possible to reduce the grazing incidence characteristic distortion.

In addition, in the present modification example, as in the embodiment described above, each of the sensor pixels 11 is provided with the four transfer transistors TRX. The three transfer transistors TRX are provided at the border between the four sensor pixels 11 adjacent to each other. This makes it possible to decrease the proportion of light entering each sensor pixel 11 that is photoelectrically converted by the respective transfer transistors TRX as compared with the proportion of light that is photoelectrically converted by the respective transfer transistors TRX disposed near the middle of each sensor pixel 11. As a result, it is possible to suppress a decrease in sensitivity. In this case, the element separator 33 is provided at the border between the two sensor pixels 11 adjacent to each other. The semiconductor layer 31 (p-type silicon layer) having an electrical conduction type different from the electrical conduction type (e.g., n type) of the photoelectric conversion element PD is present between the transfer transistors TRX and the element separator 33. In a case where the electric charge accumulated in the respective photoelectric conversion elements PD is concurrently transferred to the corresponding floating diffusions FD, this prevents the electric charge from being transferred to the floating diffusion FD different from the corresponding floating diffusion FD. As a result, it is possible to suppress a decrease in sensitivity caused by the transfer leakage of electric charge.

[Modification Example B]

In the embodiment described above, for example, as illustrated in FIG. 19, the pixel 11ir may be omitted and the pixel 11g may be provided with the two transfer transistors TRXg (TRXg1 and TRXg2), the two floating diffusions FDg (FDg1 and FDg2), and the two switching transistors SWg (SWg1 and SWg2).

In this case, the two transfer transistors TRXg (TRXg1 and TRXg2) are coupled in parallel to the cathode of the photoelectric conversion element PDg. The floating diffusion FDg1 and the switching transistor SWg1 are provided for the transfer transistor TRXg 1. The floating diffusion FDg2 and the switching transistor SWg2 are provided for the transfer transistor TRXg2. Further, the floating diffusion FDg1 and the floating diffusion FDg2 are electrically coupled through the wiring lines Lfd. In the present modification example, electric charge generated by the photoelectric conversion element PDg is accumulated in two places (FDg1 and FDg2).

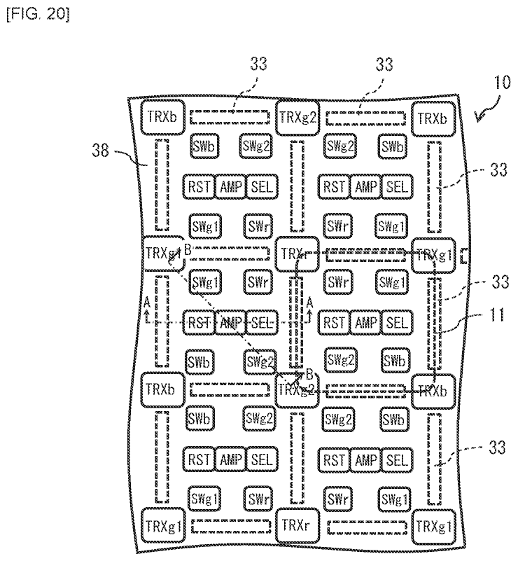

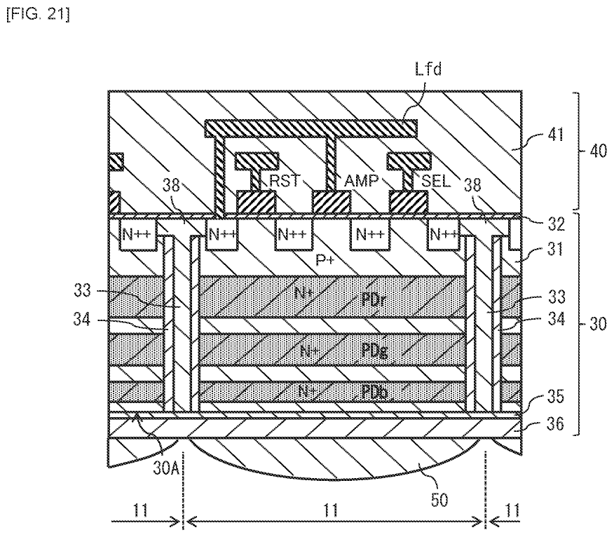

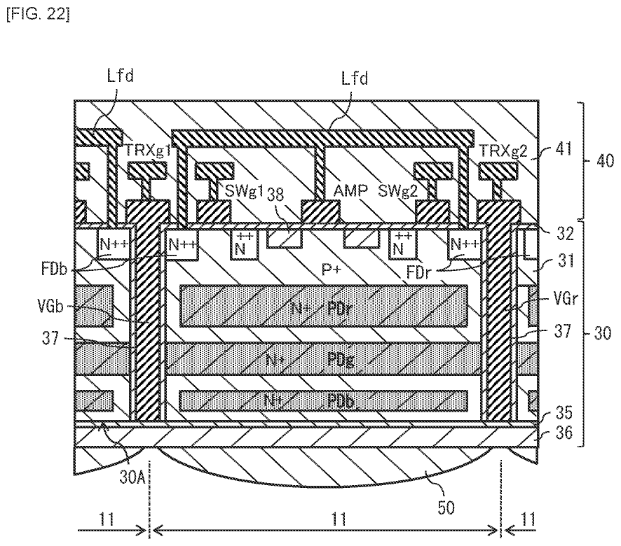

Next, a planar configuration and a cross-sectional configuration of the pixel array section 10 according to the present modification example are described. FIG. 20 illustrates an example of a planar configuration of the pixel array section 10. Each of FIGS. 21 and 22 illustrates an example of a vertical cross-sectional configuration of the pixel array section 10. FIG. 20 illustrates an example of a planar layout of the respective components other than the wiring line Lfd in the pixel array section 10 as viewed from the wiring layer 40 side. FIG. 21 illustrates an example of a cross-sectional configuration taken along the A-A line in FIG. 20. FIG. 22 illustrates an example of a cross-sectional configuration taken along the B-B line in FIG. 21. It is to be noted that the descriptions of the components similar to those of the embodiment described above are omitted as appropriate.

In the present modification example, for example, as illustrated in FIG. 20, in the sensor pixel 11 according to the embodiment described above, the transfer transistors TRXg1 and TRXg2 are provided one by one at two portions opposed to each other in the diagonal direction among the portions at which the four transfer transistors TRX are provided. Further, in the present modification example, the switching transistor SWg1 is provided adjacent to the transfer transistor TRXg1 and the switching transistor SWg2 is provided adjacent to the transfer transistor TRXg2.

In this way, in the present modification example, as in the embodiments described above, a plurality of vertical transistors (the plurality of transfer transistors TRX) provided in the respective sensor pixels 11 is disposed along the border between the two or four sensor pixels 11 adjacent to each other. This makes it possible to decrease the proportion of light entering each sensor pixel 11 that is photoelectrically converted by the respective transfer transistors TRX as compared with the proportion of light that is photoelectrically converted by the respective transfer transistors TRX disposed near the middle of each sensor pixel 11. As a result, it is possible to suppress a decrease in sensitivity.

In addition, in the present modification example, electric charge generated by the photoelectric conversion element PDg is accumulated in two places (FD1 and FDg2). This makes it possible to read out electric charge generated by the photoelectric conversion element PDg with certainty.

[Modification Example C]

In the modification example B described above, for example, as illustrated in FIG. 23, the pixel 11g may be provided with the two photoelectric conversion elements PDg (PDg1 and PDg2). In other words, the two photoelectric conversion elements PDg (PDg1 and PDg2) having the same emission color are provided in the one sensor pixel 11 in the present modification example.

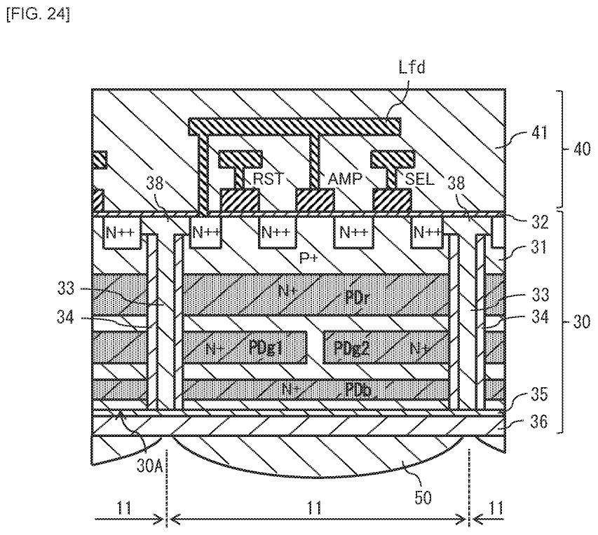

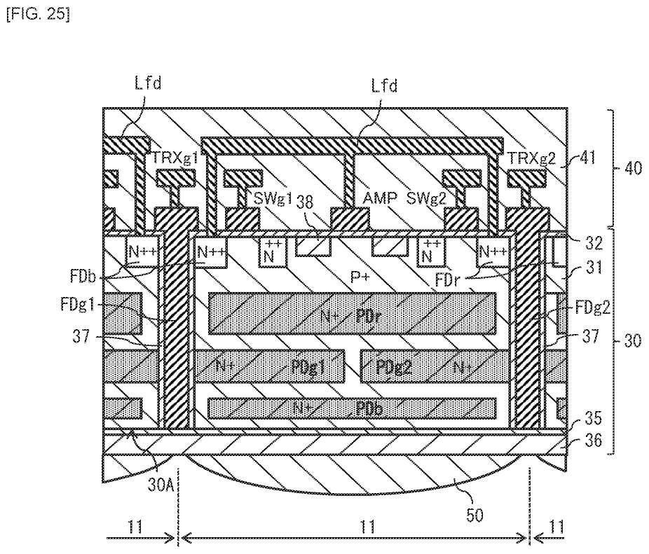

In this case, for example, as illustrated in FIGS. 24 and 25, the semiconductor layer 31 (p-type silicon layer) is provided between the photoelectric conversion element PDg1 and the photoelectric conversion element PDg2. The photoelectric conversion element PDg1 and the photoelectric conversion element PDg2 are therefore electrically separated from each other by the semiconductor layer 31 (p-type silicon layer). Each of FIGS. 24 and 25 illustrates an example of a vertical cross-sectional configuration of the pixel array section 10. FIG. 24 illustrates a modification example of the cross-sectional configuration corresponding to FIG. 21. FIG. 25 illustrates a modification example of the cross-sectional configuration corresponding to FIG. 22. It is to be noted that the descriptions of the components similar to those of the embodiment described above are omitted as appropriate.

The cathode of the photoelectric conversion element PDg1 is provided with the transfer transistor TRXg1 and the cathode of the photoelectric conversion element PDg2 is provided with the transfer transistor TRXg2. This makes it possible to achieve an image plane phase difference AF by using the two photoelectric conversion elements PDg (PDg1 and PDg2) provided in the one pixel 11g.

[Modification Example D]

In the embodiment described above, the transfer transistors TRX are used to be shared between the four sensor pixels 11, but the four transfer transistors TRX may be provided one by one for the respective sensor pixels 11, for example, as illustrated in FIG. 26. In addition, the four switching transistors SW (SWir, SWr, SWg, and SWb) may be omitted as necessary in the present modification example.

In this case, the four transfer transistors TRX (TRXir, TRXr, TRXg, and TRXb) are disposed in each of the sensor pixels 11 along the border between the two or four sensor pixels 11 adjacent to each other in a plan view. This border corresponds, for example, to a dashed line represented by the sign “11” in FIG. 26. For example, as illustrated in FIGS. 26 to 32, the four transfer transistors TRX (TRXir, TRXr, TRXg, and TRXb) are disposed side by side at positions near the border between the two or four sensor pixels 11 adjacent to each other in a plan view. For example, as illustrated in FIGS. 26 to 32, the four transfer transistors TRX (TRXir, TRXr, TRXg, and TRXb) are provided at positions at the four corners of the sensor pixel 11 near the border between the four sensor pixels 11 adjacent to each other in a plan view.

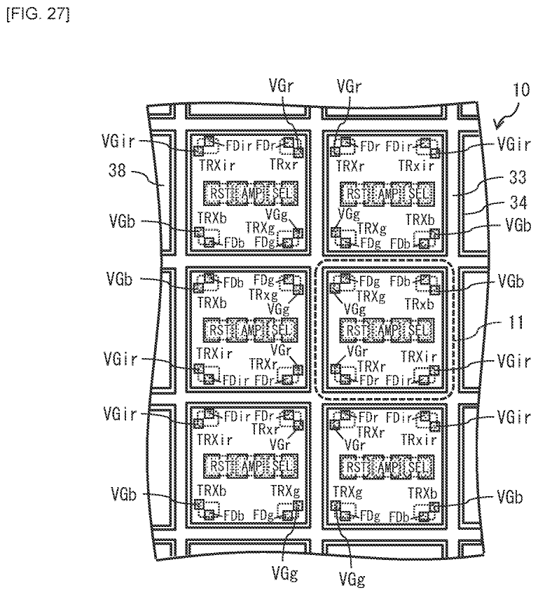

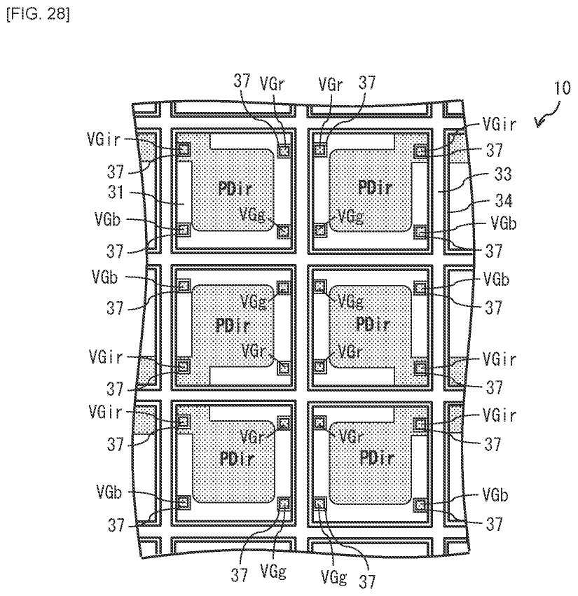

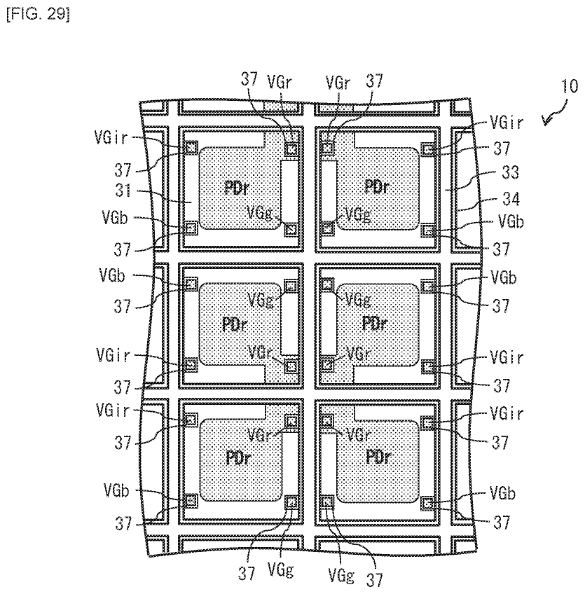

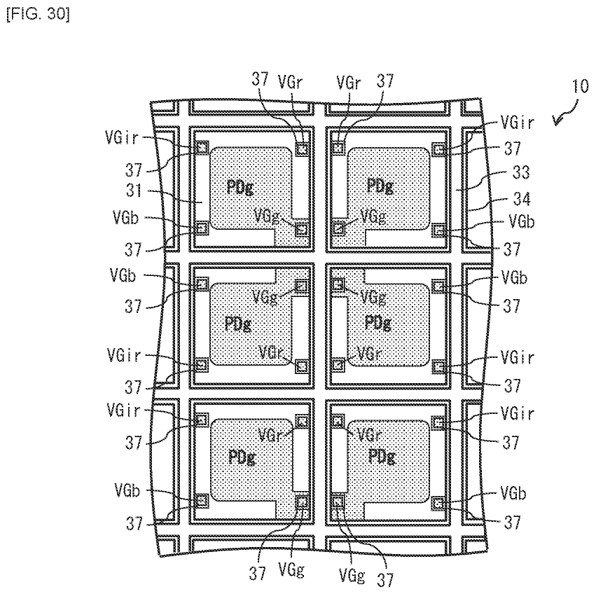

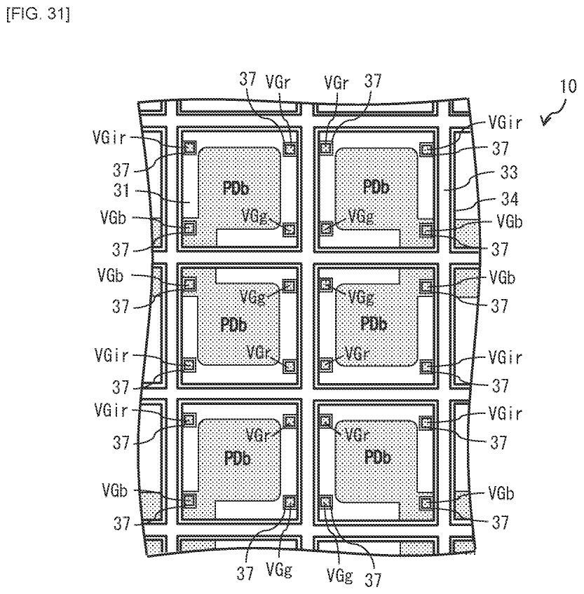

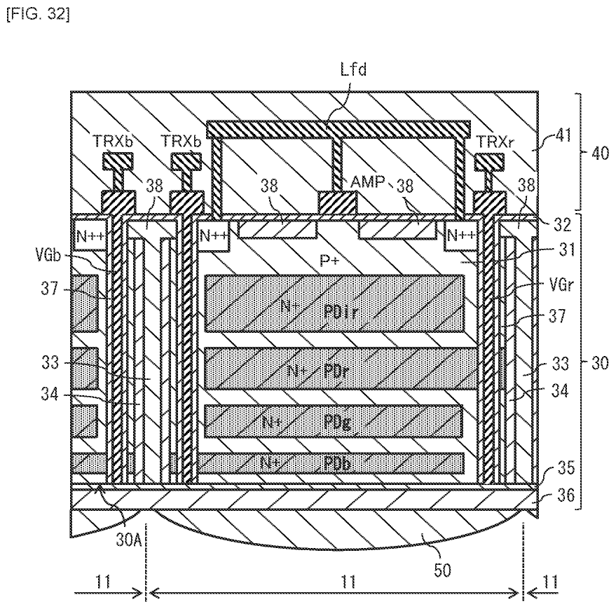

FIG. 26 illustrates an example of a planar configuration of the pixel array section 10. Each of FIGS. 27 to 31 illustrates an example of a horizontal cross-sectional configuration of the pixel array section 10. FIG. 32 illustrates an example of a vertical cross-sectional configuration of the pixel array section 10. FIG. 26 illustrates an example of a planar layout of the respective components other than the wiring line Lfd in the pixel array section 10 as viewed from the wiring layer 40 side. FIG. 27 illustrates an example of a cross-sectional configuration taken along the A-A line in FIG. 32. FIG. 28 illustrates an example of a cross-sectional configuration taken along the B-B line in FIG. 32. FIG. 29 illustrates an example of a cross-sectional configuration taken along the C-C line in FIG. 32. FIG. 30 illustrates an example of a cross-sectional configuration taken along the D-D line in FIG. 32. FIG. 31 illustrates an example of a cross-sectional configuration taken along the E-E line in FIG. 32. FIG. 32 illustrates an example of a cross-sectional configuration taken along the portion corresponding to the B-B line in FIG. 3. In the present modification example, a cross-sectional configuration at the portion corresponding to the A-A line in FIG. 3 is a cross-sectional configuration similar to the cross-sectional configuration, for example, illustrated in FIG. 9.

In the present modification example, for example, as illustrated in FIGS. 26 to 32, the element separator 33 is provided at the border between the two or four sensor pixels 11 adjacent to each other in a plan view to have a lattice shape. In each of the sensor pixels 11, the four transfer transistors TRX (TRXir, TRXr, TRXg, and TRXb) are provided at positions at the four corners of the sensor pixel 11 near the element separator 33 in a plan view. This makes it possible to decrease the proportion of light entering each sensor pixel 11 that is photoelectrically converted by the respective transfer transistors TRX as compared with the proportion of light that is photoelectrically converted by the respective transfer transistors TRX disposed near the middle of each sensor pixel 11. As a result, it is possible to suppress a decrease in sensitivity.

[Modification Example E]

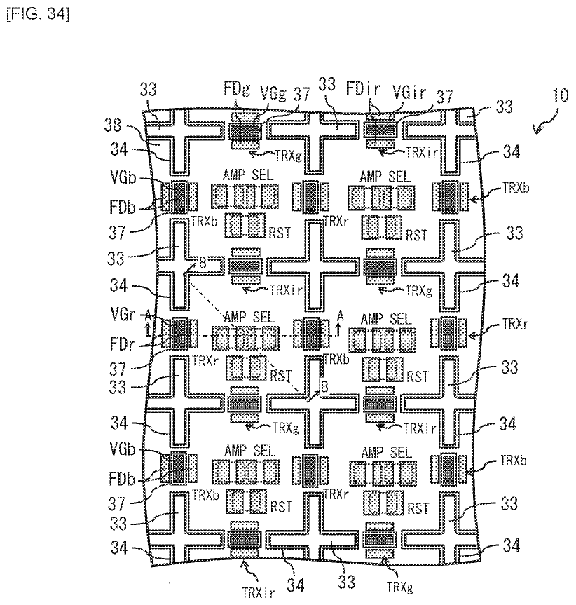

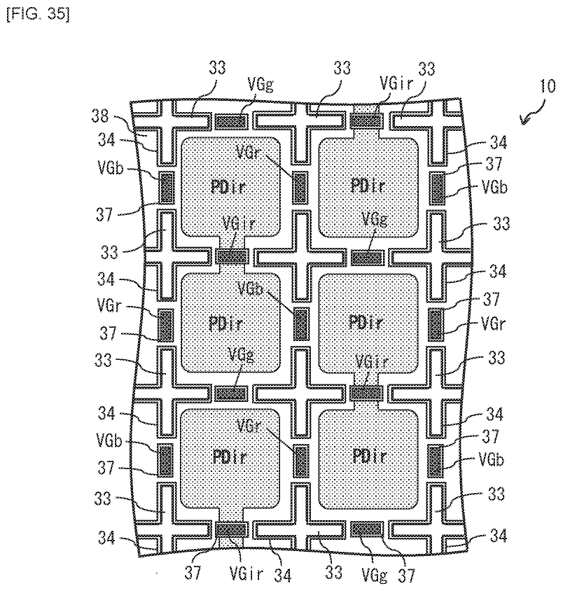

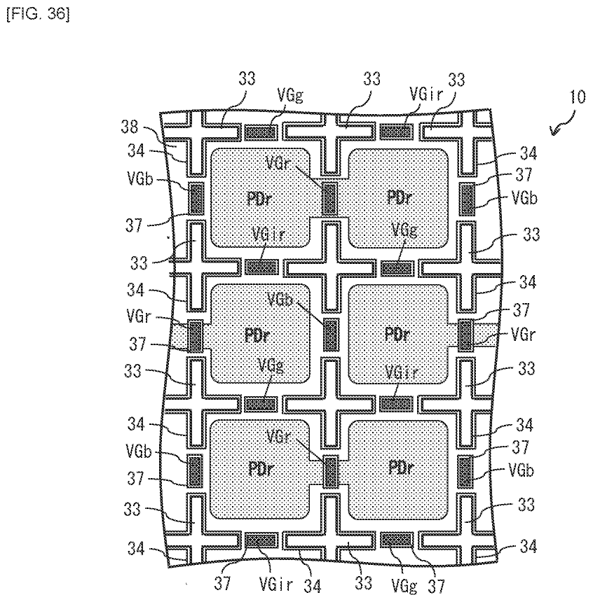

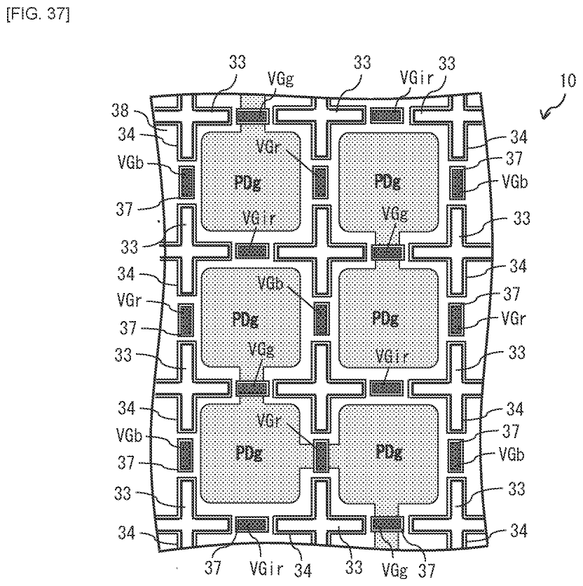

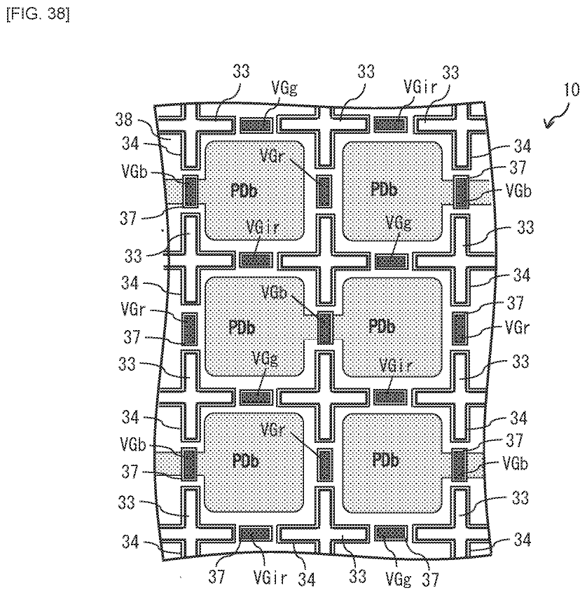

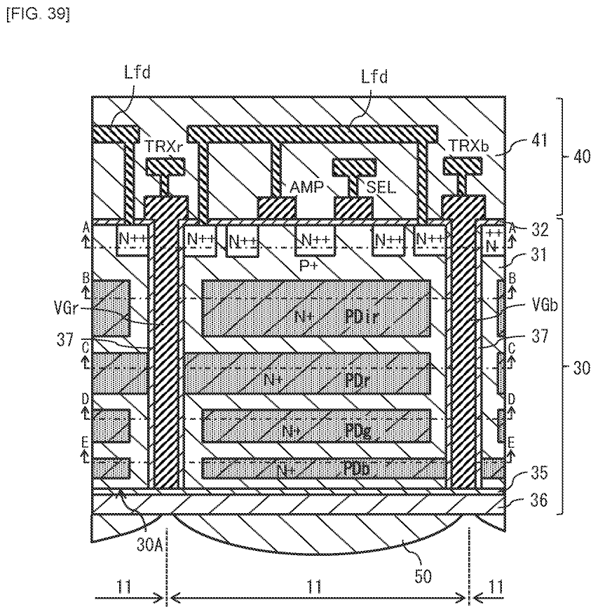

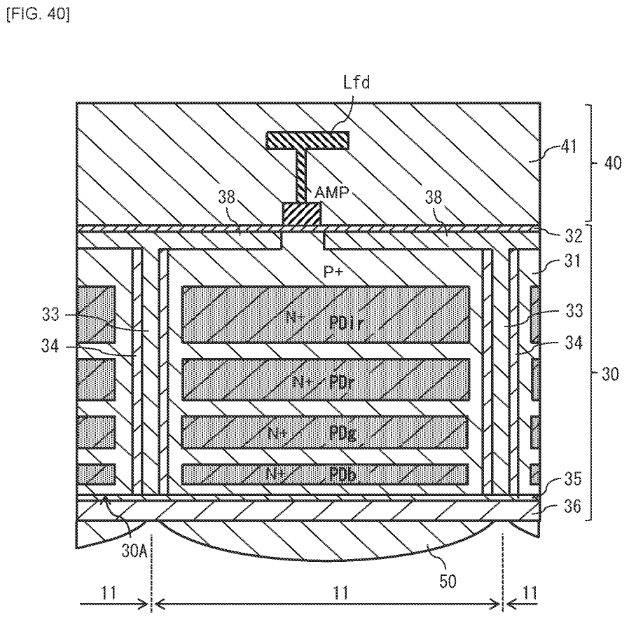

For example, as illustrated in FIGS. 33 to 40, the four transfer transistors TRX (TRXir, TRXr, TRXg, and TRXb) may be disposed in each of the sensor pixels 11 according to the modification example D described above along the border between the two sensor pixels 11 adjacent to each other. FIG. 33 illustrates an example of a planar configuration of the pixel array section 10. Each of FIGS. 34 to 38 illustrates an example of a horizontal cross-sectional configuration of the pixel array section 10. FIG. 39 illustrates an example of a vertical cross-sectional configuration of the pixel array section 10. FIG. 33 illustrates an example of a planar layout of the respective components other than the wiring line Lfd in the pixel array section 10 as viewed from the wiring layer 40 side. FIG. 34 illustrates an example of a cross-sectional configuration taken along the A-A line in FIG. 39. FIG. 35 illustrates an example of a cross-sectional configuration taken along the B-B line in FIG. 39. FIG. 36 illustrates an example of a cross-sectional configuration taken along the C-C line in FIG. 39. FIG. 37 illustrates an example of a cross-sectional configuration taken along the D-D line in FIG. 39. FIG. 38 illustrates an example of a cross-sectional configuration taken along the E-E line in FIG. 39. FIG. 39 illustrates an example of a cross-sectional configuration taken along the portion corresponding to the A-A line in FIG. 33. FIG. 40 illustrates an example of a cross-sectional configuration taken along the portion corresponding to the B-B line in FIG. 33.

The border described above corresponds, for example, to a dashed line represented by the sign “11” in FIG. 33. For example, as illustrated in FIGS. 33 to 39, the four transfer transistors TRX (TRXir, TRXr, TRXg, and TRXb) are disposed side by side at the border between the two sensor pixels 11 adjacent to each other in a plan view. For example, as illustrated in FIGS. 33 to 39, the four transfer transistors TRX (TRXir, TRXr, TRXg, and TRXb) are disposed at the border between the two sensor pixels 11 adjacent to each other in a plan view.

In this case, the vertical gate electrode VGir of the transfer transistor TRXir is shared between the two sensor pixels 11 that form the border of a portion at which the transfer transistor TRXir is disposed. In addition, the vertical gate electrode VGr of the transfer transistor TRXr is shared between the two sensor pixels 11 that form the border of a portion at which the transfer transistor TRXr is disposed. In addition, the vertical gate electrode VGg of the transfer transistor TRXg is shared between the two sensor pixels 11 that form the border of a portion at which the transfer transistor TRXg is disposed. In addition, the vertical gate electrode VGb of the transfer transistor TRXb is shared between the two sensor pixels 11 that form the border of a portion at which the transfer transistor TRXb is disposed. FIG. 39 illustrates an example in which the vertical gate electrode VGb is shared between the two sensor pixels 11 adjacent to each other and the vertical gate electrode VGr is shared between the two sensor pixels 11 adjacent to each other.

Each of the transfer transistors TRXir is provided with an equal number of (two) floating diffusions FDir to the number of sensor pixels 11 that share the transfer transistor TRXir. In each of the transfer transistors TRXir, the two floating diffusions FDir are assigned to the two respective sensor pixels 11 adjacent to each other one by one. Similarly, each of the transfer transistors TRXr is provided with an equal number of (two) floating diffusions FDr to the number of sensor pixels 11 that share the transfer transistor TRXr. In each of the transfer transistors TRXr, the two floating diffusions FDr are assigned to the two respective sensor pixels 11 adjacent to each other one by one. In addition, each of the transfer transistors TRXg is provided with an equal number of (two) floating diffusions FDr to the number of sensor pixels 11 that share the transfer transistor TRXg. In each of the transfer transistors TRXg, the two floating diffusions FDg are assigned to the two respective sensor pixels 11 adjacent to each other one by one. In addition, each of the transfer transistors TRXb is provided with an equal number of (two) floating diffusions FDr to the number of sensor pixels 11 that share the transfer transistor TRXb. In each of the transfer transistors TRXb, the two floating diffusions FDb are assigned to the two respective sensor pixels 11 adjacent to each other one by one.

For example, as illustrated in FIGS. 34 to 38, the horizontal cross-sectional shape of the vertical gate electrode VG is a rectangular shape extending along the border in each of the transfer transistors TRX. In this case, the two floating diffusions FD are disposed one by one, for example, on both sides of the rectangular shape of the vertical gate electrode VG in each of the transfer transistors TRX. It is to be noted that the horizontal cross-sectional shape of the vertical gate electrode VG is not limited to a rectangular shape.

In the two sensor pixels 11 that share the vertical gate electrode VGir of the transfer transistor TRXir, the respective photoelectric conversion elements PD_ir are in contact with the vertical gate electrode VGir through the insulating film 37, for example, as illustrated in FIG. 35. In addition, the respective photoelectric conversion elements PD_ir are in contact with the other photoelectric conversion elements PD_ir through the semiconductor layer 31 (p-type silicon layer). In other words, the semiconductor layer 31 (p-type silicon layer) is formed between the two photoelectric conversion elements PDir adjacent to each other. Further, the semiconductor layer 31 (p-type silicon layer) is formed between the vertical gate electrode VGir of the transfer transistor TRXir and the element separator 33. This electrically separates each of the photoelectric conversion elements PD_ir from the other adjacent photoelectric conversion elements PD_ir by the semiconductor layer 31 (p-type silicon layer).

In addition, the two sensor pixels 11 that share the vertical gate electrode VGr of the transfer transistor TRXr, the respective photoelectric conversion elements PD_r are in contact with the vertical gate electrode VGr through the insulating film 37, for example, as illustrated in FIG. 36. In addition, the respective photoelectric conversion elements PD_r are in contact with the other photoelectric conversion elements PD_r through the semiconductor layer 31 (p-type silicon layer). In other words, the semiconductor layer 31 (p-type silicon layer) is formed between the two photoelectric conversion elements PDr adjacent to each other. Further, the semiconductor layer 31 (p-type silicon layer) is formed between the vertical gate electrode VGr of the transfer transistor TRXr and the element separator 33. This electrically separates each of the photoelectric conversion elements PD_r from the other adjacent photoelectric conversion elements PD_r by the semiconductor layer 31 (p-type silicon layer).

In addition, the four sensor pixels 11 that share the vertical gate electrode VGg of the transfer transistor TRXg, the two photoelectric conversion elements PD_g are in contact with the vertical gate electrode VGg through the insulating film 37, for example, as illustrated in FIG. 37. In addition, the four photoelectric conversion elements PD_g are in contact with the other photoelectric conversion elements PD_g through the semiconductor layer 31 (p-type silicon layer). In other words, the semiconductor layer 31 (p-type silicon layer) is formed between the two photoelectric conversion elements PDg adjacent to each other. Further, the semiconductor layer 31 (p-type silicon layer) is formed between the vertical gate electrode VGg of the transfer transistor TRXg and the element separator 33. This electrically separates each of the photoelectric conversion elements PD_g from the other adjacent photoelectric conversion elements PD_g by the semiconductor layer 31 (p-type silicon layer).

In addition, the two sensor pixels 11 that share the vertical gate electrode VGb of the transfer transistor TRXb, the four photoelectric conversion elements PD_b are in contact with the vertical gate electrode VGb through the insulating film 37, for example, as illustrated in FIG. 38. In addition, the four photoelectric conversion elements PD_b are in contact with the other photoelectric conversion elements PD_b through the semiconductor layer 31 (p-type silicon layer). In other words, the semiconductor layer 31 (p-type silicon layer) is formed between the two photoelectric conversion elements PDb adjacent to each other. Further, the semiconductor layer 31 (p-type silicon layer) is formed between the vertical gate electrode VGb of the transfer transistor TRXb and the element separator 33. This electrically separates each of the photoelectric conversion elements PD_b from the other adjacent photoelectric conversion elements PD_b by the semiconductor layer 31 (p-type silicon layer).

In the present modification example, for example, as illustrated in FIGS. 33 to 38 and 40, the element separator 33 is provided at the border between the four sensor pixels 11 adjacent to each other in a plan view. The element separator 33 is further provided at a portion other than the border between the two sensor pixels 11 adjacent to each other in a plan view. For example, as illustrated in FIGS. 33 to 38 and 40, the element separator 33 has a cross shape along the border. In this case, the semiconductor layer 31 (p-type silicon layer) is provided between the vertical gate electrode VG of each of the transfer transistors TRX and the element separator 33. It is to be noted that the horizontal cross-sectional shape of the element separator 33 is not limited to a cross shape.

[Operation]

Next, an operation of the solid-state imaging device 1 according to the present modification example is described.

In the two sensor pixels 11 that share the vertical gate electrode VG of the transfer transistor TRX, the electric charge accumulated in the photoelectric conversion element PD of the one sensor pixel 11 (referred to as “first sensor pixel 11” below) is transferred to the floating diffusion FD through the side wall of the vertical gate electrode VG on the first sensor pixel 11 side by turning on the transfer transistor TRX. Similarly, in the two sensor pixels 11 that share the vertical gate electrode VG of the transfer transistor TRX, the electric charge accumulated in the photoelectric conversion element PD of the sensor pixel 11 (referred to as “second sensor pixel 11” below) different from the first sensor pixel 11 is transferred to the floating diffusion FD through the side wall of the vertical gate electrode VG on the second sensor pixel 11 side by turning on the transfer transistor TRX. In this way, in each of the sensor pixels 11 that share the vertical gate electrode VG of the transfer transistor TRX, the electric charge accumulated in the photoelectric conversion element PD is transferred to the corresponding floating diffusion FD.

The electric charge transferred to the floating diffusion FD is amplified by the amplification transistor AMP and outputted to the data output line VSL as a pixel signal. The signal level of the pixel signal is detected by the column signal processing circuit 22 and the resultant detection value is outputted to the outside as pixel data.

Incidentally, the electric charge accumulated in the respective photoelectric conversion elements PD is transferred to the corresponding floating diffusions FD concurrently in a case where the transfer transistor TRX is turned on. In this case, the electric charge accumulated in each of the photoelectric conversion elements PD is not transferred to the floating diffusion FD different from the corresponding floating diffusion FD. This is because the semiconductor layer 31 (p-type silicon layer) having an electrical conduction type different from the electrical conduction type (e.g., n type) of the photoelectric conversion element PD is present between the transfer transistor TRX (vertical gate electrode VG) and the element separator 33, for example, as illustrated in FIG. 35 and a potential barrier is formed between the semiconductor layer 31 (p-type silicon layer) present between the transfer transistor TRX and the element separator 33 and the vertical gate electrode VG. In other words, the two floating diffusions FD that share the vertical gate electrode VG are separated from each other by the semiconductor layer 31 (p-type silicon layer).

Next, effects of the solid-state imaging device 1 according to the present modification example are described.

In the present modification example, a plurality of vertical transistors (the plurality of transfer transistors TRX) provided in the respective sensor pixels 11 is disposed along the border between the two sensor pixels 11 adjacent to each other. This makes it possible to decrease the proportion of light entering each sensor pixel 11 that is photoelectrically converted by the respective transfer transistors TRX as compared with the proportion of light that is photoelectrically converted by the respective transfer transistors TRX disposed near the middle of each sensor pixel 11. As a result, it is possible to suppress a decrease in sensitivity.

In addition, in the present modification example, each of the sensor pixels 11 is provided with the four transfer transistors TRX. The four transfer transistors TRX are provided at the border between the two sensor pixels 11 adjacent to each other. This makes it possible to decrease the proportion of light entering each sensor pixel 11 that is photoelectrically converted by the respective transfer transistors TRX as compared with the proportion of light that is photoelectrically converted by the respective transfer transistors TRX disposed near the middle of each sensor pixel 11. As a result, it is possible to suppress a decrease in sensitivity. In this case, the element separator 33 is provided at the border between the four sensor pixels 11 adjacent to each other. The semiconductor layer 31 (p-type silicon layer) having an electrical conduction type different from the electrical conduction type (e.g., n type) of the photoelectric conversion element PD is present between the transfer transistors TRX and the element separator 33. In a case where the electric charge accumulated in the respective photoelectric conversion elements PD is concurrently transferred to the corresponding floating diffusions FD, this prevents the electric charge from being transferred to the floating diffusion FD different from the corresponding floating diffusion FD. As a result, it is possible to suppress a decrease in sensitivity caused by the transfer leakage of electric charge.

[Modification Example F]

In the embodiment described above and the modification examples thereof, for example, as illustrated in FIG. 41, the solid-state imaging device 1 may include a color filter 60 for each of the sensor pixels 11. Each of the color filters 60 is disposed, for example, between the anti-reflection film 36 and the on-chip lens 50. In the certain sensor pixel 11, the color filter 60 may include a filter 60y that selectively absorbs, for example, blue light (light in a wavelength range of 425 nm or more and 495 nm or less). The light passing through the filter 60y includes no blue light. In the other sensor pixel 11, the color filter 60 may include a filter 60b that selectively absorbs, for example, green light (light in a wavelength range of 495 nm or more and 570 nm or less) and red light (light in a wavelength range of 620 nm or more and 750 nm or less). The light passing through the filter 60b includes neither green light nor red light.

In the present modification example, the sensor pixel 11 provided with the filter 60y is provided, for example, with the three photoelectric conversion elements PDir, PDr, and PDg. This causes the three photoelectric conversion elements PDir, PDr, and PDg to photoelectrically convert the light passing through the filter 60y. In addition, in the present modification example, the sensor pixel 11 provided with the filter 60b is provided, for example, with the two photoelectric conversion elements PDir and PDb. This causes the two photoelectric conversion elements PDir and PDb to photoelectrically convert the light passing through the filter 60y. It is to be noted that FIG. 41 illustrates an example in which the sensor pixel 11 provided with the filter 60b is provided with a dummy photoelectric conversion element PDdm. The dummy photoelectric conversion element PDdm is not coupled to the pixel circuit 12.

<3. Second Embodiment>

FIG. 42 illustrates an example of a schematic configuration of an imaging system 2 according to a second embodiment of the present disclosure. The imaging system 2 includes the solid-state imaging device 1 according to any of the embodiment described above and the modification examples thereof. The imaging system 2 includes, for example, an optical system 210, a shutter device 220, the solid-state imaging device 1, a signal processing circuit 230, and a display section 240.

The optical system 210 forms an image of image light (incident light) from a subject on the imaging surface (pixel array section 10) of the solid-state imaging device 1. The shutter device 220 is disposed between the optical system 210 and the solid-state imaging device 1. The shutter device 220 controls a period in which the solid-state imaging device 1 is irradiated with light and a period in which light is blocked. The solid-state imaging device 1 receives image light (incident light) coming from the optical system 210 and outputs pixel signals (pixel signals obtained from the plurality of sensor pixels 11 in accordance with pieces of image light) corresponding to the received image light (incident light) to the signal processing circuit 230. The signal processing circuit 230 processes the pixel signal inputted from the solid-state imaging device 1 to generate image data. The signal processing circuit 230 further generates an image signal corresponding to the generated image data and outputs the image signal to the display section 240. The display section 240 displays an image based on the image signal inputted from the signal processing circuit 230.

In the present application example, the solid-state imaging device 1 according to any of the embodiment described above and the modification examples thereof is provided in the imaging system 2. This makes it possible to achieve a system in which an image having high sensitivity and small grazing incidence characteristic distortion is used.

<4. Practical Application Examples>

[Practical Application Example 1]

The technology (the present technology) according to the present disclosure is applicable to a variety of products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a vessel, or a robot.

FIG. 43 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 43, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 43, an audio speaker 12061, a display section 12062, and an instrument panel 12063 are illustrated as the output device. The display section 12062 may, for example, include at least one of an on-board display and a head-up display.

FIG. 44 is a diagram depicting an example of the installation position of the imaging section 12031.

In FIG. 1022, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 44 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The above has described the example of the mobile body control system to which the technology according to the present disclosure may be applied. The technology according to the present disclosure may be applied to the imaging section 12031 among the components described above. Specifically, the solid-state imaging device 1 according to any of the first embodiment described above and the modification examples thereof is applicable to the imaging section 12031. The application of the technology according to the present disclosure to the imaging section 12031 makes it possible to obtain an image having high sensitivity and small grazing incidence characteristic distortion. This makes it possible to perform control with high accuracy.

[Practical Application Example 2]

FIG. 45 is a view depicting an example of a schematic configuration of an endoscopic surgery system to which the technology according to an embodiment of the present disclosure (present technology) can be applied.

In FIG. 45, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

FIG. 46 is a block diagram depicting an example of a functional configuration of the camera head 11102 and the CCU 11201 depicted in FIG. 45.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The above has described the example of the endoscopic surgery system to which the technology according to the present disclosure may be applied. The technology according to the present disclosure may be favorably applied to the image pickup unit 11402 provided to the camera head 11102 of the endoscope 11100 among the components described above. Specifically, the solid-state imaging device 1 according to any of the first embodiment described above and the modification examples thereof is applicable to the image pickup unit 11402. The application of the technology according to the present disclosure to the image pickup unit 11402 makes it possible to obtain an image having high sensitivity and small grazing incidence characteristic distortion. This makes it possible to provide the endoscope 11100 having high image quality.

Although the present disclosure has been described above with reference to the embodiments and the modification examples thereof, the application example thereof, and the practical application examples thereof, the present disclosure is not limited to the embodiments or the like, but may be modified in a variety of ways. It is to be noted that the effects described herein are merely illustrative. The effects of the present disclosure are not limited to the effects described herein. The present disclosure may have effects other than the effects described herein.

In addition, the present disclosure may also have the following configurations.

(1) A solid-state imaging device including:

a light receiving surface; and

a plurality of pixels that is disposed in a matrix at positions opposed to the light receiving surface, in which each of the pixels includes
a plurality of photoelectric conversion sections having different depths from the light receiving surface, the plurality of photoelectric conversion sections each photoelectrically converting light coming through the light receiving surface,
a plurality of electric charge holding sections one or more of which are provided for each of the photoelectric conversion sections, the plurality of electric charge holding sections each holding electric charge transferred from the corresponding photoelectric conversion section, and
a plurality of transfer transistors one or more of which are provided for each of the photoelectric conversion sections, the plurality of transfer transistors each including a vertical gate electrode that reaches at least the corresponding photoelectric conversion section and transferring electric charge from the corresponding photoelectric conversion section to the corresponding electric charge holding section,
the plurality of transfer transistors being disposed along a border between the two or four pixels adjacent to each other.

(2) The solid-state imaging device according to (1), in which each of the pixels is provided with the three or four transfer transistors,
the three or four transfer transistors being provided at the border between the four pixels adjacent to each other, and

the solid-state imaging device further includes:
an element separator that is provided at the border between the two pixels adjacent to each other; and
a semiconductor layer that is provided between the transfer transistors and the element separator and has an electrical conduction type different from an electrical conduction type of each of the photoelectric conversion sections.

(3) The solid-state imaging device according to (2), in which an equal number of the electric charge holding sections to a number of the sensor pixels sharing each of the transfer transistors are assigned for each of the transfer transistors and separated from each other by the semiconductor layer.

(4) The solid-state imaging device according to (1), in which each of the pixels is provided with the four transfer transistors,
the four transfer transistors being provided at the border between the two pixels adjacent to each other, and
the solid-state imaging device further includes:

an element separator that is provided at the border between the four pixels adjacent to each other; and

a semiconductor layer that is provided between the transfer transistors and the element separator and has an electrical conduction type different from an electrical conduction type of each of the photoelectric conversion sections.

(5) The solid-state imaging device according to (4), in which an equal number of the electric charge holding sections to a number of the sensor pixels sharing each of the transfer transistors are assigned for each of the transfer transistors and separated from each other by the semiconductor layer.

(6) The solid-state imaging device according to (1), in which each of the pixels is provided with the four transfer transistors, and the four transfer transistors are provided at positions at four corners of each of the pixels near the border between the four pixels adjacent to each other.

(7) An electronic apparatus including:

a solid-state imaging device that acquires an image by performing imaging; and

a signal processor that processes the image obtained by the solid-state imaging device, in which the solid-state imaging device includes

a light receiving surface, and

a plurality of pixels that is disposed in a matrix at positions opposed to the light receiving surface,

each of the pixels including a plurality of photoelectric conversion sections having different depths from the light receiving surface, the plurality of photoelectric conversion sections each photoelectrically converting light coming through the light receiving surface,

a plurality of electric charge holding sections one or more of which are provided for each of the photoelectric conversion sections, the plurality of electric charge holding sections each holding electric charge transferred from the corresponding photoelectric conversion section, and

a plurality of transfer transistors one or more of which are provided for each of the photoelectric conversion sections, the plurality of transfer transistors each including a vertical gate electrode that reaches at least the corresponding photoelectric conversion section and transferring electric charge from the corresponding photoelectric conversion section to the corresponding electric charge holding section,

the plurality of transfer transistors being disposed along a border between the two or four pixels adjacent to each other.

The solid-state imaging device and the electronic apparatus according to the respective embodiments of the present disclosure each have the plurality of transfer transistors disposed along the border between the two or four pixels adjacent to each other in each of the pixels. This makes it possible to reduce the proportion of light entering each pixel that is photoelectrically converted by the respective transfer transistors as compared with the proportion of light that is photoelectrically converted by the respective transfer transistors disposed near the middle of each pixel. This makes it possible to suppress a decrease in sensitivity.

This application claims the priority on the basis of Japanese Patent Application No. 2020-118067 filed on Jul. 8, 2020 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A solid-state imaging device comprising:
a light receiving surface; and
a plurality of pixels that is disposed in a matrix at positions opposed to the light receiving surface, wherein each of the pixels includes
a plurality of photoelectric conversion sections having different depths from the light receiving surface, the plurality of photoelectric conversion sections each photoelectrically converting light coming through the light receiving surface,
a plurality of electric charge holding sections one or more of which are provided for each of the photoelectric conversion sections, the plurality of electric charge holding sections each holding electric charge transferred from the corresponding photoelectric conversion section, and
a plurality of transfer transistors one or more of which are provided for each of the photoelectric conversion sections, the plurality of transfer transistors each including a vertical gate electrode that reaches at least the corresponding photoelectric conversion section and transferring electric charge from the corresponding photoelectric conversion section to the corresponding electric charge holding section,
the plurality of transfer transistors being disposed along a border between the two or four pixels adjacent to each other.

2. The solid-state imaging device according to claim 1, wherein each of the pixels is provided with the three or four transfer transistors,
the three or four transfer transistors being provided at the border between the four pixels adjacent to each other, and
the solid-state imaging device further comprises:
an element separator that is provided at the border between the two pixels adjacent to each other; and
a semiconductor layer that is provided between the transfer transistors and the element separator and has an electrical conduction type different from an electrical conduction type of each of the photoelectric conversion sections.

3. The solid-state imaging device according to claim 2, wherein an equal number of the electric charge holding sections to a number of the sensor pixels sharing each of the transfer transistors are assigned for each of the transfer transistors and separated from each other by the semiconductor layer.

4. The solid-state imaging device according to claim 1, wherein
each of the pixels is provided with the four transfer transistors, the four transfer transistors being provided at the border between the two pixels adjacent to each other, and
the solid-state imaging device further comprises:
an element separator that is provided at the border between the four pixels adjacent to each other; and
a semiconductor layer that is provided between the transfer transistors and the element separator and has an electrical conduction type different from an electrical conduction type of each of the photoelectric conversion sections.

5. The solid-state imaging device according to claim 4, wherein an equal number of the electric charge holding sections to a number of the sensor pixels sharing each of the transfer transistors are assigned for each of the transfer transistors and separated from each other by the semiconductor layer.

6. The solid-state imaging device according to claim 1, wherein
each of the pixels is provided with the four transfer transistors, and
the four transfer transistors are provided at positions at four corners of each of the pixels near the border between the four pixels adjacent to each other.

7. An electronic apparatus comprising:
a solid-state imaging device that acquires an image by performing imaging; and
a signal processor that processes the image obtained by the solid-state imaging device, wherein
the solid-state imaging device includes a light receiving surface, and
a plurality of pixels that is disposed in a matrix at positions opposed to the light receiving surface, each of the pixels including
a plurality of photoelectric conversion sections having different depths from the light receiving surface, the plurality of photoelectric conversion sections each photoelectrically converting light coming through the light receiving surface,
a plurality of electric charge holding sections one or more of which are provided for each of the photoelectric conversion sections, the plurality of electric charge holding sections each holding electric charge transferred from the corresponding photoelectric conversion section, and
a plurality of transfer transistors one or more of which are provided for each of the photoelectric conversion sections, the plurality of transfer transistors each including a vertical gate electrode that reaches at least the corresponding photoelectric conversion section and transferring electric charge from the corresponding photoelectric conversion section to the corresponding electric charge holding section,
the plurality of transfer transistors being disposed along a border between the two or four pixels adjacent to each other.
